(19) United States
(12) Patent Application Publication
(10) Pub. No.: US 2024/0223071 A1
(43) Pub. Date: Jul. 4, 2024

(54) SWITCHING MODULE

(71) Applicant: Murata Manufacturing Co., Ltd., Nagaokakyo-shi (JP)

(72) Inventor: Kazuo HATTORI, Nagaokakyo-shi (JP)

(21) Appl. No.: 18/215,273

(22) Filed: Jun. 28, 2023

Related U.S. Application Data
(63) Continuation of application No. PCT/JP2021/036951, filed on Oct. 6, 2021.

(30) Foreign Application Priority Data
Jan. 7, 2021 (JP) 2021-001301

(51) Int. Cl. H02M 1/32; G01R 31/52; H02H 1/00; H02H 7/12; H02M 5/293

(52) U.S. Cl. CPC H02M 1/32; G01R 31/52; H02H 1/0007; H02H 7/1216; H02M 5/293

(57) ABSTRACT

In a switching module, a determiner of a controller performs a first determination, in which a commander controls relays of first bidirectional switches to an opened state and controls relays of second bidirectional switches to a closed state by outputting an opening command signal to the relays of the first bidirectional switches and outputs a closing command signal to the relays of the second bidirectional switches, and the determiner determines that at least one of the relays of the first bidirectional switches controlled to the opened state has a short-circuit fault in a case where a difference voltage between a voltage measured by a voltmeter connected to the relay of one of the first bidirectional switches controlled to the opened state and a voltage measured by a voltmeter is within a preset voltage range.

### CROSS REFERENCE TO RELATED APPLICATIONS

This application claims the benefit of priority to Japanese Patent Application No. 2021-001301 filed on Jan. 7, 2021 and is a Continuation Application of PCT Application No. PCT/JP2021/036951 filed on Oct. 6, 2021. The entire contents of each application are hereby incorporated herein by reference.

### BACKGROUND OF THE INVENTION

### 1. Field of the Invention

The present invention relates to a switching module.

### 2. Description of the Related Art

A switching module has been proposed that includes three input terminals connected to a three-phase three-wire system three-phase alternating-current power source in which single-phase alternating-current power sources are delta-connected, three output terminals connected to a load, three bidirectional switches connected between the input terminals and the output terminals, a first voltmeter that measures a voltage between the input terminals, a second voltmeter that measures a voltage between the output terminals, and a determination unit that determines whether or not the bidirectional switches have a short-circuit failure on the basis of a difference voltage between a first voltage measured by the first voltmeter and a second voltage measured by the second voltmeter when the bidirectional switches are in an open state (see, for example, International Publication No. 2020/137237).

In a case where a three-phase four-wire system three-phase alternating-current power source in which single-phase alternating-current power sources are Y-connected or a single-phase three-wire system alternating-current power source is used, a switching module is typically used in a state where a bidirectional switch is connected between a neutral terminal of the power source and a load. In this case, for example, in a case where impedances of loads connected to output terminals corresponding to three phases of the switching module are equal, a difference in an opened state or a closed state of the bidirectional switch connected between the neutral terminal and the load does not appear as a difference voltage between a voltage between input terminals and a voltage between the output terminals. Therefore, there is a possibility that a fault of a plurality of bidirectional switches used in the switching module including the bidirectional switch connected between the neutral terminal and the load are left unattended.

### SUMMARY OF THE INVENTION

Preferred embodiments of the present invention provide switching modules that are each able to detect the presence or absence of a fault for all switches included in the switching module.

A switching module according to a preferred embodiment of the present invention is connected to an alternating-current power source including a plurality of polar terminals to output alternating-current voltages having different phases and a neutral terminal, the switching module includes a plurality of first input terminals each connected to a corresponding one of the plurality of polar terminals, a plurality of first switches each connected in series with a corresponding one of the plurality of first input terminals, a second input terminal connected to the neutral terminal of the alternating-current power source, a second switch connected in series with the second input terminal, a plurality of first output terminals each electrically connected to a corresponding one of the plurality of first input terminals with a corresponding one of the first switches interposed therebetween, a second output terminal electrically connected to the second input terminal with the second switch interposed therebetween, a controller configured or programmed to control each of the plurality of first switches and the second switch, first voltmeters to measure a first voltage between a corresponding one of the plurality of first input terminals and the second input terminal, and second voltmeters to measure a second voltage between a corresponding one of the plurality of first output terminals and the second output terminal, wherein the controller is configured or programmed to perform a first determination, in which the controller controls any one of the plurality of first switches to an opened state, controls all other the first switches to a closed state, and controls the second switch to an opened state, and determines that at least one of the first switch controlled to the closed state and the second switch have a short-circuit fault where a difference voltage between a first voltage measured by the first voltmeter connected to the first switch controlled to the opened state and the second voltage is within a preset voltage range.

A switching module according to a preferred embodiment of the present invention may be configured such that, in addition to the first determination, the controller may be configured or programmed to perform a second determination, in which the controller controls the any one of the plurality of first switches to an opened state and controls the plurality of first switches excluding the first switch controlled to the opened state and the second switch to a closed state, and determines that the first switch controlled to the opened state has a short-circuit fault where the difference voltage between a first voltage of the first voltmeter connected to the first switch controlled to the opened state and the second voltage is within the voltage range and determines that the second switch has a short-circuit fault in a case where the difference voltage is outside the voltage range.

A switching module according to a preferred embodiment of the present invention may further include a plurality of first switching elements each connected in parallel with a corresponding one of the plurality of first switches, and a second switching element connected in parallel with the second switch, wherein the controller is configured or programmed to control the plurality of first switching elements and the second switching element to an ON state while the plurality of first switches are in an opened state, and where there is a phase for which the difference voltage is outside the voltage range, the controller is configured or programmed to determine that a first switching element corresponding to the phase for which the difference voltage is outside the voltage range has an open fault.

A switching module according to a preferred embodiment of the present invention may be configured such that the controller is configured or programmed to control the plurality of first switches to a closed state while the plurality of first switching elements are in an OFF state, and where there is a phase for which the difference voltage between the first voltage and the second voltage is outside the preset voltage range, the controller is configured or programmed to determine that a first switch corresponding to the phase for which the difference voltage is outside the voltage range has an open fault.

A switching module according to a preferred embodiment of the present invention may be configured such that the controller is configured or programmed to control the second switching element to an ON state while any one of the plurality of first switches and a first switching element connected in parallel with the any one of the plurality of first switches are in an opened state and the second switch is in an opened state, and where a difference voltage between the second voltage measured by the second voltmeter connected to the second switching element and a first voltage of the first voltmeter connected to the first switch controlled to the opened state is outside the voltage range, the controller is configured or programmed to determine that the second switching element has an open fault.

A switching module according to a preferred embodiment of the present invention may be configured such that the controller is configured or programmed to control the second switch to an opened state while the plurality of first switches are in a closed state and the second switching element is in an OFF state, and where the difference voltage corresponding to the second switch is outside the voltage range, the controller is configured or programmed to determine that the second switch has an open fault.

A switching module according to a preferred embodiment of the present invention is connected to an alternating-current power source including a plurality of polar terminals to output alternating-current voltages having different phases and a neutral terminal, the switching module includes a plurality of first input terminals each connected to a corresponding one of the plurality of polar terminals, a plurality of first switches each connected in series with a corresponding one of the plurality of first input terminals, a second input terminal connected to the neutral terminal of the alternating-current power source, a second switch connected in series with the second input terminal, first output terminals each electrically connected to a corresponding one of the plurality of first input terminals with a corresponding one of the first switches interposed therebetween, a second output terminal electrically connected to the second input terminal with the second switch interposed therebetween, a controller configured or programmed to control each of the plurality of first switches and the second switch, first ammeters to measure a first current flowing through a corresponding one of the plurality of first switches, and a second ammeter to measure a second current flowing through the second switch, wherein the controller is configured or programmed to perform a first determination, in which the controller controls any one of the plurality of first switches to an opened state and controls the plurality of first switches excluding the first switch controlled to the opened state and the second switch to a closed state, and determines that the first switch controlled to the opened state has a short-circuit fault in a case where a current value of the first current is outside a preset current range.

A switching module according to a preferred embodiment of the present invention may be configured such that, in addition to the first determination, the controller may be configured or programmed to perform a second determination, in which the controller controls the any one of the plurality of first switches and the second switch to an opened state and the plurality of first switches excluding the first switch controlled to the opened state to a closed state, and determines that the second switch has a short-circuit fault in a case where a current value of the second current is outside the current range.

A switching module according to a preferred embodiment of the present invention may further include a plurality of first switching elements each connected in parallel with a corresponding one of the plurality of first switches, and a second switching element connected in parallel with the second switch between the second input terminal and the second output terminal, wherein the controller is configured or programmed to control the plurality of first switching elements to an ON state while the plurality of first switches are in an opened state and the second switching element is in an ON state, and where there is a first switching element for which the current value of the first current is within the current range, the controller is configured or programmed to determine that the first switching element for which the current value of the first current is within the current range has an open fault.

A switching module according to a preferred embodiment of the present invention may be configured such that the controller is configured or programmed to control the plurality of first switches to a closed state and to control at least one of the second switching element and the second switch to a closed state while the plurality of first switching elements are in an ON state, and where there is a phase for which the current value of the first current is within the current range, the controller is configured or programmed to determine that a first switch corresponding to the phase for which the current value of the first current is within the current range has an open fault.

A switching module according to a preferred embodiment of the present invention may be configured such that the controller is configured or programmed to control the second switching element to an ON state while any one of the plurality of first switches and the second switch are in an opened state, other first switches are in a closed state, and first switching elements connected in parallel with the first switches that are in the closed state are in an OFF state, and where the current value of the second current is within the current range, the controller is configured or programmed to determine that the second switching element has an open fault.

A switching module according to a preferred embodiment of the present invention may be configured such that the controller is configured or programmed to control the second switch to a closed state while the plurality of first switches are in a closed state and the second switching element is in an OFF state, and where the current value of the second current is within the current range, the controller is configured or programmed to determine that the second switch has an open fault.

According to preferred embodiments of the present invention, a controller may be configured or programmed to perform a first determination, in which the controller controls any one of the plurality of first switches and the second switch to an opened state and controls all other first switches to a closed state, and determines that at least one of the first switch controlled to the opened state and the second switch have a short-circuit fault in a case where a difference voltage between a first voltage measured by the first voltmeter connected to the first switch controlled to the opened state and the second voltage measured by the second voltmeter is within a preset voltage range. Therefore, even in a case where impedances of loads connected to the plurality of first output terminals are equal or substantially equal, it is possible to determine whether or not the second switch connected between the second input terminal and the second output terminal has a fault, and it is therefore possible to detect the presence or absence of a fault for all of the first switches and the second switch included in the switching module.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 schematically illustrates a configuration of a power source system according to Preferred Embodiment 1 of the present invention.

FIG. 2 is a circuit diagram of a power conversion unit according to Preferred Embodiment 1 of the present invention.

FIG. 3 is a circuit diagram of a module body according to Preferred Embodiment 1 of the present invention.

FIG. 4 illustrates an example of information stored in a test case storage according to Preferred Embodiment 1 of the present invention.

FIG. 5 is an explanatory view for explaining operation of a switching module according to Preferred Embodiment 1 of the present invention.

FIG. 6A is an explanatory view for explaining operation of the switching module according to Preferred Embodiment 1 of the present invention and illustrates a state of determining whether or not a bidirectional switch 1A or a bidirectional switch 1D has a short-circuit fault.

FIG. 6B is an explanatory view for explaining operation of the switching module according to Preferred Embodiment 1 of the present invention and illustrates a state of determining whether or not the bidirectional switch 1A has a short-circuit fault.

FIG. 7A illustrates voltage vectors of output terminals te3A, te3B, te3C, and te3D in a case where bidirectional switches 1A, 1B, 1C, and 1D of the switching module according to Preferred Embodiment 1 of the present invention are in a closed state.

FIG. 7B illustrates voltage vectors of the output terminals te3A, te3B, te3C, and te3D in a case where the bidirectional switches 1A and 1D of the switching module according to Preferred Embodiment 1 of the present invention are in an opened state and the bidirectional switches 1B and 1C are in a closed state.

FIG. 8 is an explanatory view for explaining operation of the switching module according to Preferred Embodiment 1 of the present invention.

FIG. 9 is a flowchart illustrating fault determining processing performed by a controller according to Preferred Embodiment 1 of the present invention.

FIG. 10 is flowchart illustrating the fault determining processing performed by the controller according to Preferred Embodiment 1 of the present invention.

FIG. 11 is flowchart illustrating the fault determining processing performed by the controller according to Preferred Embodiment 1 of the present invention.

FIG. 12 is a flowchart illustrating the fault determining processing performed by the controller according to Preferred Embodiment 1 of the present invention.

FIG. 13 is a flowchart illustrating the fault determining processing performed by the controller according to Preferred Embodiment 1 of the present invention.

FIG. 14 illustrates voltage vectors of the output terminals te3A, te3B, te3C, and te3D in a case where the bidirectional switch 1D of the switching module according to Preferred Embodiment 1 of the present invention is in an opened state and the bidirectional switches 1A, 1B, and 1C are in a closed state.

FIG. 15 schematically illustrates a configuration of a power source system according to Preferred Embodiment 2 of the present invention.

FIG. 16 illustrates an example of information stored in a test case storage according to Preferred Embodiment 2 of the present invention.

FIG. 17 is a flowchart illustrating fault determining processing performed by a controller according to Preferred Embodiment 2 of the present invention.

FIG. 18 is 10 flowchart illustrating the fault determining processing performed by the controller according to Preferred Embodiment 2 of the present invention.

FIG. 19 is a flowchart illustrating the fault determining processing performed by the controller according to Preferred Embodiment 2 of the present invention.

FIG. 20 is a flowchart illustrating the fault determining processing performed by the controller according to Preferred Embodiment 2 of the present invention.

FIG. 21 schematically illustrates a configuration of a power source system according to Preferred Embodiment 3 of the present invention.

FIG. 22 is a flowchart illustrating fault determining processing performed by a controller according to Preferred Embodiment 3 of the present invention.

FIG. 23 is a flowchart illustrating the fault determining processing performed by the controller according to Preferred Embodiment 3 of the present invention.

FIG. 24 is flowchart illustrating the fault determining processing performed by the controller according to Preferred Embodiment 3 of the present invention.

FIG. 25 is a flowchart illustrating the fault determining processing performed by the controller according to Preferred Embodiment 3 of the present invention.

### DETAILED DESCRIPTION OF THE PREFERRED EMBODIMENTS

Preferred embodiments of the present invention will be described in detail with reference to the drawings.

### Preferred Embodiment 1

Preferred Embodiment 1 of the present invention is described in detail below with reference to the drawings. A switching module according to the present preferred embodiment is, for example, connected to a three-phase four-wire system alternating-current power source including three polar terminals that output phase voltages and a neutral terminal. The switching module includes three first input terminals that are connected to the respective three polar terminals of the alternating-current power source, a second input terminal connected to the neutral terminal, a plurality of first output terminals electrically connected to the respective three first input terminals, and a second output terminal electrically connected to the second input terminal. Furthermore, the switching module includes three first switches connected in series with the respective three first input terminals, a second switch connected in series between the second input terminal and the second output terminal, first voltmeters that measure first voltages between the first input terminals and the second input terminal, second voltmeters that measure second voltages between the first output terminals and the second output terminal, and a controller configured or programmed to control the three first switches and the second switch. The controller is configured or programmed to perform a first determination, in which the controller controls any one of the three first switches to an opened state, controls the other two first switches to a closed state, and controls the second switch to the opened state, and determines that at least one of the first switch controlled to an opened state and the second switch has a short-circuit fault in a case where a difference voltage between a first voltage measured by the first voltmeter connected to the first switch controlled to an opened state and the second voltage is within a preset voltage range. Furthermore, in addition to the first determination, the controller performs a second determination, in which the controller controls any one of the three first switches to an opened state and controls the other two first switches and the second switch to a closed state, and determines that the first switch controlled to the opened state has a short-circuit fault in a case where a difference voltage between a first voltage of the first voltmeter connected to the first switch controlled to an opened state and the second voltage is within the voltage range and determines that the second switch has a short-circuit fault in a case where the difference voltage is outside the voltage range.

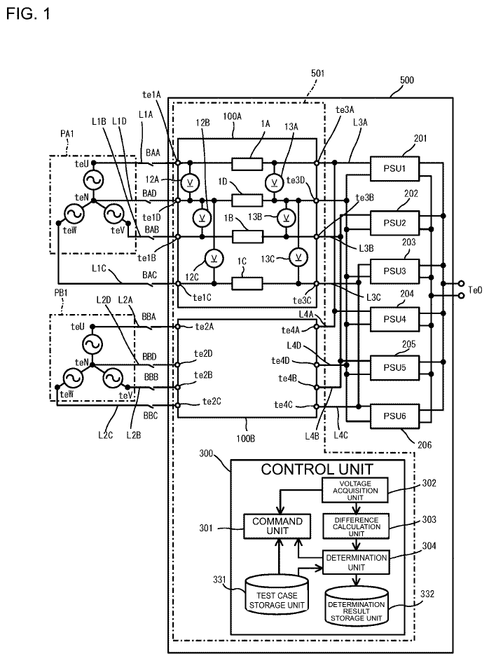

A power source system according to the present preferred embodiment is, for example, an uninterruptible power source system to supply power to a server of a data center. For example, as illustrated in FIG. 1, this power source system 500 receives alternating-current power from an alternating-current power source PA1 or a standby alternating-current power source PB1 and supplies direct-current power to a load such as a server (not illustrated) connected to an output terminal TeO. The alternating-current power source PA1 includes three alternating-current power sources that are Y-connected, and includes three polar terminals teu, teV, and teW that output phase voltages of U, V, and W phases and a neutral terminal teN. The alternating-current power source PA1 supplies a three-phase alternating current to the power source system 500 through four power wires LIA, LIB, LIC, and LID that are connected to the polar terminals teU, teV, and teW and the neutral terminal teN, respectively. The alternating-current power source PB1 also includes three alternating-current power sources that are Y-connected, and includes three polar terminals teU, teV, and teW and a neutral terminal teN. The alternating-current power source PB1 also supplies a three-phase alternating current to the power source system 500 through four power wires L2A, L2B, L2C, and L2D that are connected to the polar terminals teU, teV, and teW and the neutral terminal teN, respectively. Furthermore, breakers BAA, BAB, BAC, BAD, BBA, BBB, BBC, and BBD are provided on the power wires L1A, L1B, L1C, L1D, L2A, L2B, L2C, and L2D, respectively.

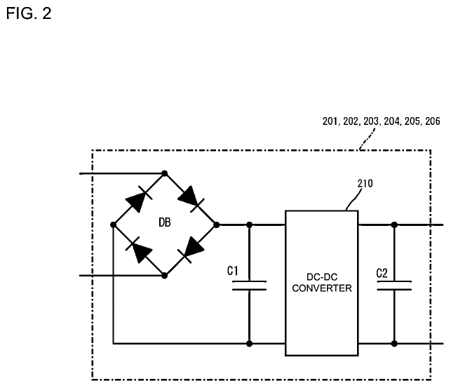

The power source system 500 includes six power conversion circuits 201, 202, 203, 204, 205, and 206 and a switching module 501. The switching module 501 includes two module bodies 100A and 100B and a controller 300 that controls operation of the two module bodies 100A and 100B. Each of the power conversion circuits 201, 202, 203, 204, 205, and 206 includes a rectifying circuit DB, a smoothing capacitor C1 connected between output terminals of the rectifying circuit DB, a DC-DC converter 210 that boosts or lowers a direct-current voltage generated between both ends of the capacitor C1 and outputs the direct-current voltage thus boosted or lowered, and a capacitor C2 to reduce a ripple current connected between output terminals of the DC-DC converter 210, for example, as illustrated in FIG. 2. The DC-DC converter 210 includes, for example, an inductor, a switching element, and a drive circuit that drives the switching element. The drive circuit controls output of the DC-DC converter 210 by outputting a pulse width modulation (PWM) signal or a pulse frequency modulation (PFM) signal to the switching element based on a command value information indicative of a command value of an output voltage input from the controller 300. Output ends of the DC-DC converter 210 are connected to a pair of output terminals teo of the power source system 500.

See FIG. 1 again. The module body 100A includes input terminals te1A, te1B, te1C, and te1D and output terminals te3A, te3B, te3C, and te3D. The input terminals te1A, te1B, te1C, and telD are connected to the power wires L1A, L1B, L1C, and L1D connected to the alternating-current power source PA, respectively. The output terminals te3A, te3B, te3C and te3D are connected to power wires L3A, L3B, L3C, and L3D connected to the power conversion circuits 201, 202, 203, 204, 205, and 206. The module body 100B also includes input terminals te2A, te2B, te2C, and te2D and output terminals te4A, te4B, te4C, and te4D. The input terminals te2A, te2B, te2C, and te2D are connected to the power wires L2A, L2B, L2C, and L2D connected to the standby alternating-current power source PB, respectively. The output terminals te4A, te4B, te4C, and te4D are connected to power wires L4A, L4B, L4C, and L4D connected to the power conversion circuits 201, 202, 203, 204, 205, and 206. Furthermore, the module body 100A includes four bidirectional switches 1A, 1B, 1C, and 1D and six voltmeters 12A, 12B, 12C, 13A, 13B, and 13C. Note that the module body 100B also has a configuration similar to the module body 100A, and includes four bidirectional switches (not illustrated) and six voltmeters (not illustrated).

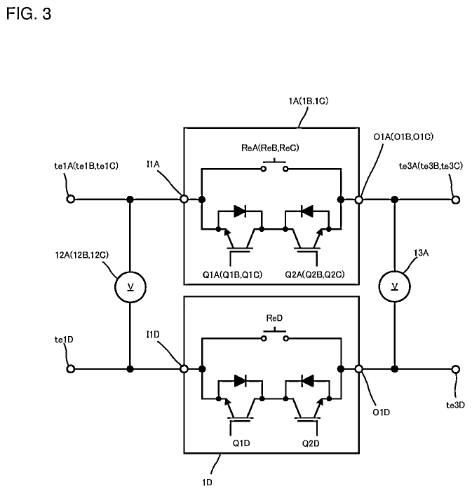

The bidirectional switch 1A is connected in series between the input terminal te1A and the output terminal te3A. The bidirectional switch 1B is connected in series between the input terminal te1B and the output terminal te3B. The bidirectional switch 1C is connected in series between the input terminal te1C and the output terminal te3C. The bidirectional switch 1D is connected in series between the input terminal te1D and the output terminal te3D. The bidirectional switch 1A (1B, 1C) has one relay ReA (ReB, ReC) and two switching elements Q1A and Q2A (Q1B and Q2B, Q1C and Q2C), as illustrated in FIG. 3. The bidirectional switch 1D also has one relay ReD and two switching elements Q1D and Q2D. The relays ReA, ReB, and ReC are first switches that are mechanical relays, semiconductor relays, or the like. The relay ReD is a second switch having a configuration similar to the relays ReA, ReB, and ReC. The relay ReA (ReB, ReC) is connected between the input terminal te1A (te1B, te1C) and the output terminal te3A (te3B, te3C).

The switching elements Q1A and Q2A (Q1B and Q2B, Q1C and Q2C) are, for example, insulated gate bipolar transistors (IGBT) and are first switching elements connected in series with each other and are connected in parallel with the relay ReA (ReB, ReC). The switching elements Q1D and Q2D are, for example, IGBTs and are second switching element connected in series with each other and are connected in parallel with the relay ReD. Collectors of the switching elements Q1A and Q2A are connected to each other, and cathodes of body diodes of the switching elements Q1A and Q2A are connected to each other. The collector and an anode of the body diode of the switching element Q1A are connected to the input terminal te1A, and the collector and an anode of the body diode of the switching element Q2A are connected to the output terminal te3A. The switching elements Q1B and Q2B are also connected to the input terminal te1B and the output terminal te3B in a similar manner to the switching elements Q1A and Q2A, and the switching elements Q1C and Q2C are also connected to the input terminal te1C and the output terminal te3C in a similar manner to the switching elements Q1A and Q2A. Collectors of the switching elements Q1B, Q1C and Q2B, Q2C are connected to each other, and cathodes of body diodes of the switching elements Q1B, Q1C and Q2B, Q2C are connected to each other. The collector and an anode of the body diode of the switching element Q1B, Q1C are connected to the input terminal te1A, and the collector and an anode of the body diode of the switching element Q2B, Q2C are connected to the output terminal te3A. Collectors of the switching elements Q1D and Q2D are connected to each other, and cathodes of body diodes of the switching elements Q1D and Q2D are connected to each other. The collector and an anode of the body diode of the switching element Q1D are connected to the input terminal te1D, and the collector and an anode of the body diode of the switching element Q2A are connected to the output terminal te3D.

The voltmeter 12A is connected between an input end I1A of the bidirectional switch 1A and an input end I1D of the bidirectional switch 1D, and the voltmeter 12B is connected between an input end I1B of the bidirectional switch 1B and the input end I1D of the bidirectional switch 1D. The voltmeter 12C is connected between an input end I1C of the bidirectional switch 1C and the input end I1D of the bidirectional switch 1D. The voltmeter 12A is a first voltmeter that measures a voltage value of a first voltage corresponding to a potential difference between a point between the input terminal te1A and the bidirectional switch 1A and a point between the input terminal te1D and the bidirectional switch 1D. The voltmeter 12B is a first voltmeter that measures a voltage value of a first voltage corresponding to a potential difference between a point between the input terminal te1B and the bidirectional switch 1B and a point between the input terminal te1D and the bidirectional switch 1D. The voltmeter 12C is a first voltmeter that measures a voltage value of a first voltage corresponding to a potential difference between a point between the input terminal te1C and the bidirectional switch 1C and a point between the input terminal te1D and the bidirectional switch 1D. Each of the voltmeters 12A, 12B, and 12C continuously outputs a voltage signal reflecting a measured voltage value to the controller 300.

The voltmeter 13A is connected between an output end O1A of the bidirectional switch 1A and an output end O1D of the bidirectional switch 1D, and the voltmeter 13B is connected between an output end O1B of the bidirectional switch 1B and the output end O1D of the bidirectional switch 1D. The voltmeter 13C is connected between an output end O1C of the bidirectional switch 1C and the output end O1D of the bidirectional switch 1D. The voltmeter 13A is a second voltmeter that measures a voltage value of a second voltage corresponding to a potential difference between a point between the output terminal te3A and the bidirectional switch 1A and a point between the output terminal te3D and the bidirectional switch 1D. The voltmeter 13B is a second voltmeter that measures a voltage value of a second voltage corresponding to a potential difference between a point between the output terminal te3B and the bidirectional switch 1B and a point between the output terminal te3D and the bidirectional switch 1D. The voltmeter 13C is a second voltmeter that measures a voltage value of a second voltage corresponding to a potential difference between a point between the output terminal te3C and the bidirectional switch 1C and a point between the output terminal te3D and the bidirectional switch 1D. Each of the voltmeters 12A, 12B, and 12C continuously outputs a voltage signal indicative of a measured voltage value to the controller 300.

See FIG. 1. The controller 300 includes, for example, a microcomputer and a memory and controls operation of the module bodies 100A and 100B. The controller 300 is configured or programmed to include a command unit 301, a voltage acquisition unit 302, a difference calculation unit 303, and a determination unit 304. The switching module 501 may be configured such that the module bodies 100A and 100B and the controller 300 are incorporated into a single package or may be configured such that the module bodies 100A and 100B and the controller 300 are incorporated into difference packages. Alternatively, the switching module 501 may be configured such that the module bodies 100A and 100B and the determination unit 304 and the memory of the controller 300 are incorporated into one package and the command unit 301 of the controller 300 is incorporated into another package. Alternatively, the switching module 501 may be configured such that the module bodies 100A and 100B and the command unit 301 and the memory of the controller 300 are incorporated into one package and the determination unit 304 of the controller 300 is incorporated into another package.

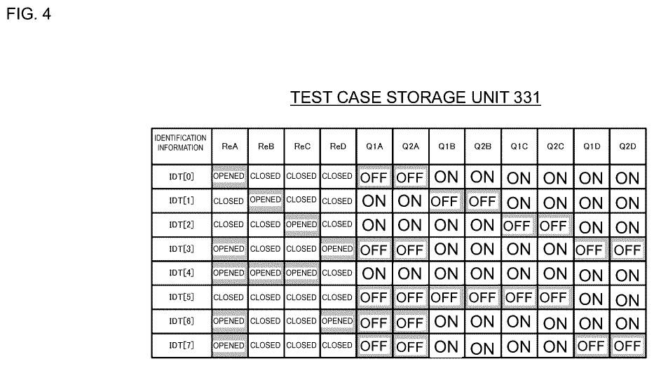

The memory includes a determination result storage 332 that stores therein determination result information indicative of a result of determination performed by the determination unit 304 as to whether or not the bidirectional switches 1A, 1B, 1C, and 1D have a fault and a test case storage 331. The test case storage 331 stores therein eight kinds of test case information indicative of combinations of opened and closed states of the relays ReA, ReB, ReC, and ReD of the bidirectional switches 1A, 1B, 1C, and 1D and ON and OFF states of the switching elements Q1A, Q2A, Q1B, Q2B, Q1C, Q2C, Q1D, and Q2D in association with identification information ID[0], ID[1], . . . , and ID[7], for example, as illustrated in FIG. 4.

See FIG. 1 again. The command unit 301 controls opened or closed states of the relays ReA, ReB, ReC, and ReD by separately outputting opening command signals to shift the relays ReA, ReB, ReC, and ReD into an opened state or closing command signals to shift the relays ReA, ReB, ReC, and ReD into a closed state to the relays ReA, ReB, ReC, and ReD. The command unit 301 controls ON or OFF states of the switching elements Q1A, Q2A, Q1B, Q2B, Q1C, Q2C, Q1D, and Q2D by separately outputting ON command signals to shift the switching elements Q1A, Q2A, Q1B, Q2B, Q1C, Q2C, Q1D, and Q2D into an ON state or OFF command signals to shift the switching elements Q1A, Q2A, Q1B, Q2B, Q1C, Q2C, Q1D, and Q2D into an OFF state to the switching elements Q1A, Q2A, Q1B, Q2B, Q1C, Q2C, Q1D, and Q2D.

In a case where the three-phase alternating-current power source PA supplies power to the power source system 500, the command unit 301 shifts the four bidirectional switches 1A, 1B, 1C, and 1D of the module body 100A into a closed state and shifts the four bidirectional switches (not illustrated) of the module body 100B into an opened state by outputting control signals to the module bodies 100A and 100B. On the other hand, in a case where the standby three-phase alternating current power source PB supplies power to the power source system 500, the command unit 301 shifts the four bidirectional switches 1A, 1B, 1C, and 1D of the module body 100A into an opened state and shifts the four bidirectional switches (not illustrated) of the module body 100B into a closed state by outputting control signals to the module bodies 100A and 100B. The command unit 301 shifts the switching elements Q1A, Q2A, Q1B, Q2B, Q1C, and Q2C into an ON state or an OFF state by outputting control signals to gate terminals of the switching elements Q1A, Q2A, Q1B, Q2B, Q1C, and Q2C. Furthermore, the command unit 301 switches an opened or closed state of at least one of the relays ReA, ReB, ReC, and ReD and an ON or OFF state of at least one of the switching elements Q1A, Q2A, Q1B, Q2B, Q1C, Q2C, Q1D, and Q2D on the basis of the test case information stored in the test case storage 331 upon notification of test period start command information or test period end command information, which will be described later, received from the voltage acquisition unit 302.

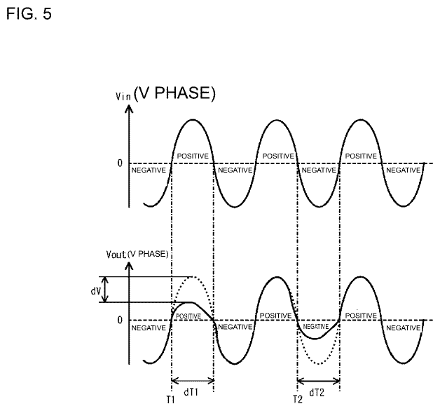

The voltage acquisition unit 302 samples measurement signals input from the voltmeters 12A, 12B, and 12C and the voltmeters 13A, 13B, and 13C for a preset sampling period, converts the sampled measurement signals into voltage value information indicative of voltage values, and notifies the difference calculation unit 303 of the voltage value information. The voltage acquisition unit 302 notifies the command unit 301 and the difference calculation unit 303 of test period start notification information when a time corresponding to a zero cross point of a phase voltage arrives on the basis of voltage information acquired by the voltage acquisition unit 302. In a case where a polarity of a phase voltage indicated by the acquired voltage information switches from a negative state to a positive state after passing a zero cross point, the voltage acquisition unit 302 notifies the command unit 301 and the difference calculation unit 303 of test period start notification information indicative of start of a test period of a positive polarity. On the other hand, in a case where a polarity of a phase voltage indicated by the acquired voltage information switches from a positive state to a negative state after passing a zero cross point, the voltage acquisition unit 302 notifies the command unit 301 and the difference calculation unit 303 of test period start notification information indicative of start of a test period of a negative polarity. The voltage acquisition unit 302 notifies the command unit 301 and the difference calculation unit 303 of test period end notification information when a preset test period elapses from a time corresponding to a zero cross point of a phase voltage on the basis of voltage information acquired by the voltage acquisition unit 302. The voltage acquisition unit 302 notifies the command unit 301 and the difference calculation unit 303 of test period start notification information when a time T1 (T2) corresponding to a zero cross point of the V-phase voltage arrives on the basis of voltage information of a V-phase voltage acquired by the voltage acquisition unit 302, for example, as illustrated in FIG. 5. The voltage acquisition unit 302 notifies the command unit 301 and the difference calculation unit 303 of test period start notification information indicative of start of a positive test period at the time T1 and notifies the command unit 301 and the difference calculation unit 303 of test period start notification information indicative of start of a negative test period at the time T2. The voltage acquisition unit 302 notifies the command unit 301 and the difference calculation unit 303 of test period end notification information when a test period dT1 (dT2) elapses from the time T1. A length of the test period dT1 (dT2) is set equal to or less than ½ of a set period of an alternating current output from the three-phase alternating current power source PA or PB and is, for example, set to 6 msec. The command unit 301 shifts the relays ReA and ReD into an opened state upon notification of test period start notification information, and the command unit 301 shifts the relays ReA and ReD into an opened state upon notification of test period end notification information.

See FIG. 1 again. The difference calculation unit 303 calculates an absolute value of a difference voltage between a voltage value measured by the voltmeter 12A and a voltage value measured by the voltmeter 13A on the basis of voltage value information received from the voltage acquisition unit 302. Furthermore, the difference calculation unit 302 calculates an absolute value of a difference voltage between a voltage value measured by the voltmeter 12B and a voltage value measured by the voltmeter 13B and calculates an absolute value of a difference voltage between a voltage value measured by the voltmeter 12C and a voltage value measured by the voltmeter 13C. When the difference calculation unit 303 is notified of test period start notification information by the voltage acquisition unit 302, every time voltage value information indicative of a voltage value measured by the voltmeter 12B and voltage value information indicative of a voltage value measured by the voltmeter 13B are received from the voltage acquisition unit 302, the difference calculation unit 303 calculates an absolute value of a difference voltage between the voltages indicated by these pieces of voltage value information. Then, the difference calculation unit 302 notifies the determination unit 304 of difference voltage information indicative of the calculated absolute value of the difference voltage. On the other hand, the difference calculation unit 303 ends calculation of an absolute value of a difference voltage upon notification of test period end notification information received from the voltage acquisition unit 302. The difference calculation unit 303 starts calculation of an absolute value of a difference voltage between a V-phase voltage Vin (V phase) measured by the voltmeter 12B and a V-phase voltage Vout (V phase) measured by the voltmeter 13B and notification of difference voltage information indicative of the calculated absolute value to the determination unit 304 when the time T1 (T2) of notification of test period start notification information arrives, for example, as illustrated in FIG. 5. Then, the difference calculation unit 303 ends calculation of an absolute value of a difference voltage when the test period dT1 (dT2) having a length of ½ of a period of a V-phase alternating-current voltage elapses from the time T1.

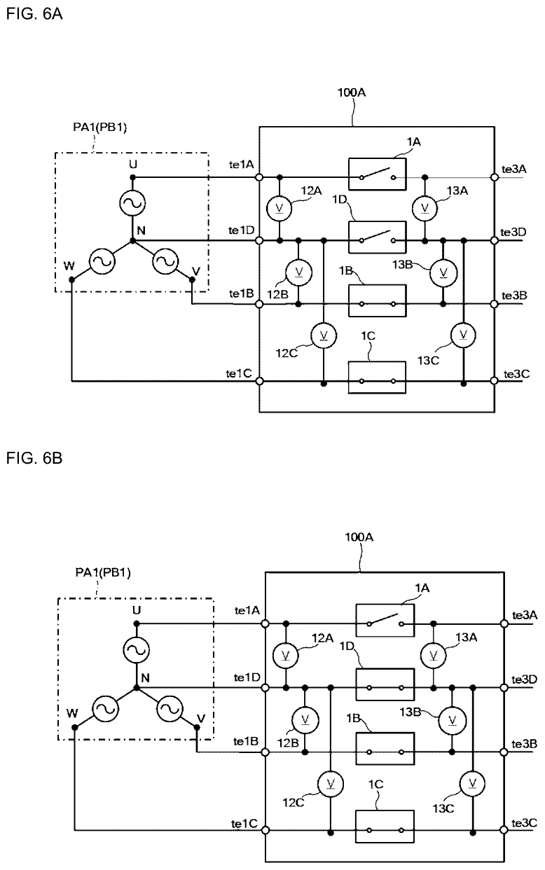

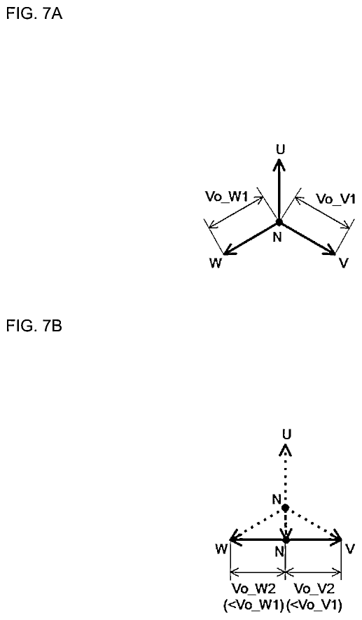

See FIG. 1 again. The determination unit 304 determines whether or not the bidirectional switches 1A, 1B, 1C, and 1D have a fault by performing fault determining processing, which will be described later. In a case where the determination unit 304 determines whether or not the relay ReA of the bidirectional switch 1A and the relay ReD of the bidirectional switch 1D have a short-circuit fault, the command unit 301 outputs an opening command signal to the relay ReA of the bidirectional switch 1A and the relay ReD of the bidirectional switch 1D and outputs a closing command signal to the relay ReB of the bidirectional switch 1B and the relay ReC of the bidirectional switch 1C. In this case, the command unit 301 outputs an OFF command signal to the switching elements Q1A, Q2A, Q1D, and Q2D and outputs an ON command signal to the switching elements Q1B, Q2B, Q1C, and Q2C. In a case where the relay ReA of the bidirectional switch 1A and the relay ReD of the bidirectional switch 1D are normal, the relays ReA and ReD are opened, as illustrated in FIG. 6A. In a case where impedances of the power conversion circuits 201, 202, 203, 204, 205, and 206 viewed from the switching module 1 side are equal to one another, voltage amplitudes Vo_U1, Vo_V1, and Vo_W1 of a U-phase voltage, a V-phase voltage, and a W-phase voltage measured by the voltmeters 13A, 13B, and 13C are equal, as illustrated in FIG. 7A. In this case, voltage amplitudes Vi_U, Vi_V, and Vi_W of a U-phase voltage, a V-phase voltage, and a W-phase voltage measured by the voltmeters 12A, 12B, and 12C are equal to the voltage amplitudes Vo_U1, Vo_V1, and Vo_W1 measured by the voltmeters 13A, 13B, and 13C. In a case where the relays ReA and ReD are in an opened state and the relays ReB and ReC are in a closed state as illustrated in FIG. 6A, a potential of the output terminal te3D changes, and thereby voltage amplitudes Vo_V2 and Vo_W2 of the V-phase voltage and the W-phase voltage become smaller than the voltage amplitudes Vo_V1 and Vo_W1, as illustrated in FIG. 7B. This generates a difference between the voltage amplitudes Vi_V and Vi_W of the V-phase voltage and the W-phase voltage measured by the voltmeters 12B and 12C and the voltage amplitudes Vo_V2 and Vo_W2 of the V-phase voltage and the W-phase voltage measured by the voltmeters 13B and 13C. By utilizing this phenomenon, the determination unit 304 determines that the relays ReA and ReD to which an opening command signal is output are normally in an opened state in accordance with the opening command signal and the relays ReA and ReD are normal in a case where an absolute value of a difference voltage indicated by difference voltage information received from the difference calculation unit 303 is larger than a preset difference voltage threshold value in a state where the command unit 301 outputs an opening command signal to the relay ReA of the bidirectional switch 1A and the relay ReD of the bidirectional switch 1D and outputs a closing command signal to the relays ReB and ReC. The difference voltage threshold value is, for example, set equal to or less than about 10% of a voltage effective value of each phase voltage, and is set to approximately 15 V in a case where a voltage effective value of each phase voltage is about 200 V. The determination unit 304 determines that the relays ReA and ReD are normal in a case where a state where the absolute value of the difference voltage is larger than the difference voltage threshold value, that is, a state where the difference voltage is outside a preset voltage range continues for a preset determination period. The determination period is, for example, set to about 3 msec. The voltage range corresponds to a voltage value range that uses, as a lower limit, a negative voltage value whose absolute value is equal to the difference voltage threshold value and uses, as an upper limit, a positive voltage value whose absolute value is equal to the difference voltage threshold value. In this case, a voltage amplitude of a voltage value Vin (V phase) of a V-phase voltage measured by the voltmeter 13B during the test period dT1 (dT2) becomes smaller than a voltage amplitude of a voltage value Vin (V phase) of a V-phase voltage measured by the voltmeter 12B during the test period dT1 (dT2), for example, as illustrated in FIG. 5.

On the other hand, in a case where the absolute value of the difference voltage indicated by the difference voltage information received from the difference calculation unit 303 is equal to or smaller than the difference voltage threshold value, that is, in a case where the difference voltage is within the voltage range in a state where the command unit 301 outputs an opening command signal to the relays ReA and ReD and outputs a closing command signal to the relays ReB and ReC, the determination unit 304 performs first determination of determining that at least one of the relays ReA and ReD to which the opening command signal is output maintains a closed state irrespective of the opening command signal and at least one of the relays ReA and ReD has a short-circuit fault. Note that in a case where the determination unit 304 determines whether or not the relay ReB of the bidirectional switch 1B and the relay ReD of the bidirectional switch 1D have a short-circuit fault, the command unit 301 outputs an opening command signal to the relays ReB and ReD and outputs a closing command signal to the relays ReA and ReC. In a case where the determination unit 304 determines whether or not the relays ReC and ReD have a short-circuit fault, the command unit 301 outputs an opening command signal to the relays ReC and ReD and outputs a closing command signal to the relays ReA and ReB.

In a case where the determination unit 304 determines whether or not the relay ReA of the bidirectional switch 1A has a short-circuit fault, the command unit 301 outputs an opening command signal to the relay ReA of the bidirectional switch 1A and outputs a closing command signal to the relays ReB, ReC, and ReD. In this case, the command unit 301 outputs an OFF command signal to the switching elements Q1A and Q2A and outputs an ON command signal to the switching elements Q1B, Q2B, Q1C, Q2C, Q1D, and Q2D. In a case where the relay ReA of the bidirectional switch 1A is normal, the relay ReA shift to an opened state, as illustrated in FIG. 6B. In this case, a difference is generated between a voltage amplitude of a U-phase voltage measured by the voltmeter 12A and a voltage amplitude of a U-phase voltage measured by the voltmeter 13A. By utilizing this phenomenon, the determination unit 304 determines that the relay ReA to which an opening command signal is output is normally in an opened state in accordance with the opening command signal and the relay ReA is normal in a case where an absolute value of a difference voltage between the voltage amplitude measured by the voltmeter 12A and the voltage amplitude measured by the voltmeter 13A is larger than the difference voltage threshold value, that is, in a case where the difference voltage is outside the voltage range in a state where the command unit 301 outputs an opening command signal to the relay ReA of the bidirectional switch 1A and outputs a closing command signal to the relays ReB, ReC, and ReD. On the other hand, in a case where the absolute value of the difference voltage between the voltage amplitude measured by the voltmeter 12A and the voltage amplitude measured by the voltmeter 13A is equal to or smaller than the difference voltage threshold value, that is, in a case where the difference voltage is within the voltage range in a state where the command unit 301 outputs an opening command signal to the relay ReA of the bidirectional switch 1A and outputs a closing command signal to the relays ReB, ReC, and ReD, the determination unit 304 performs second determination of determining that the relay ReA to which the opening command signal is output maintains a closed state irrespective of the opening command signal and has a short-circuit fault.

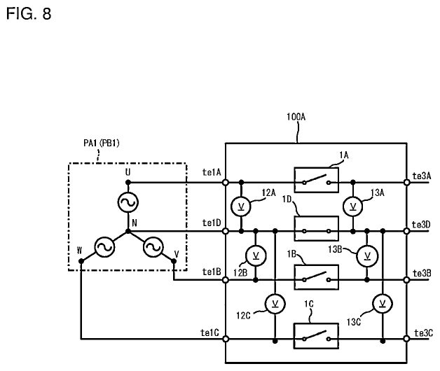

Furthermore, in a case where the determination unit 304 determines whether or not the switching elements Q1A, Q2A, Q1B, Q2B, Q1C, and Q2C have an open fault, the command unit 301 outputs an opening command signal to the relays ReA, ReB, and ReC and outputs a closing command signal to the relay ReD. This shifts the relays ReA, ReB, and ReC into an opened state and shifts the relay ReD into a closed state, as illustrated in FIG. 8. In this case, the command unit 301 outputs an ON command signal to all of the switching elements Q1A, Q2A, Q1B, Q2B, Q1C, and Q2C. In a case where the switching elements Q1A, Q2A, Q1B, Q2B, Q1C, and Q2C include a switching element for which an absolute value of a difference voltage indicated by difference voltage information received from the difference calculation unit 303 is larger than the difference voltage threshold value, that is, the difference voltage is outside the voltage range in a state in which the relays ReA, ReB, and ReC are in an opened state and the relay ReD is in a closed state, the determination unit 304 determines that the switching element maintains an OFF state irrespective of the ON command signal and has an open fault.

In a case where the determination unit 304 determines whether or not the relays ReA, ReB, and ReC have an open fault, the command unit 301 outputs an OFF command signal to the Q1A, Q2A, Q1B, Q2B, Q1C, and Q2C and outputs a closing command signal to the relay ReD. This shifts the switching elements Q1A, Q2A, Q1B, Q2B, Q1C, and Q2C into an OFF state and shifts the relay ReD into a closed state. In this case, the command unit 301 outputs a closing command signal to all of the relays ReA, ReB, and ReC. In a case where the relays ReA, ReB, and ReC include a relay for which an absolute value of a difference voltage indicated by difference voltage information received from the difference calculation unit 303 is larger than the difference voltage threshold value, that is, the difference voltage is outside the voltage range in a state in which the switching elements Q1A, Q2A, Q1B, Q2B, Q1C, and Q2C are in an OFF state and the relay ReD is in a closed state, the determination unit 304 determines that the relay maintains an opened state irrespective of the closing command signal and have an open fault.

Furthermore, in a case where the determination unit 304 determines whether or not the switching elements Q1D and Q2D have an open fault, the command unit 301 outputs an opening command signal to the relays ReA and ReD and outputs an OFF command signal to Q1A and Q2A. Furthermore, the command unit 301 outputs an ON command signal to Q1D and Q2D. The switching elements Q1B, Q2B, Q1C, and Q2C are in an ON state, and the switching elements Q1A and Q2A are in an OFF state. The relays ReB and ReC are in a closed state. In a case where an absolute value of a difference voltage indicated by V-phase or W-phase difference voltage information received from the difference calculation unit 303 is larger than the difference voltage threshold value, that is, the difference voltage is outside the voltage range in this state, the determination unit 304 determines that the switching elements Q1D and Q2D maintain an OFF state irrespective of the ON command signal and have an open fault.

In a case where the determination unit 304 determines whether or not the relay ReD has an open fault, the command unit 301 outputs an opening command signal to the relay ReA and outputs an OFF command signal to Q1A, Q2A, Q1D, and Q2D. The command unit 301 outputs a closing command signal to the relay ReD. The switching elements Q1B, Q2B, Q1C, and Q2C are in an ON state, and the relays ReB and ReC are in a closed state. In a case where an absolute value of a difference voltage indicated by difference voltage information received from the difference calculation unit 303 is larger than the difference voltage threshold value in this state, the determination unit 304 determines that the relay ReD maintains an opened state irrespective of the closing command signal and has an open fault. The determination unit 304 causes information indicative of a determination result to be stored in the determination result storage 332.

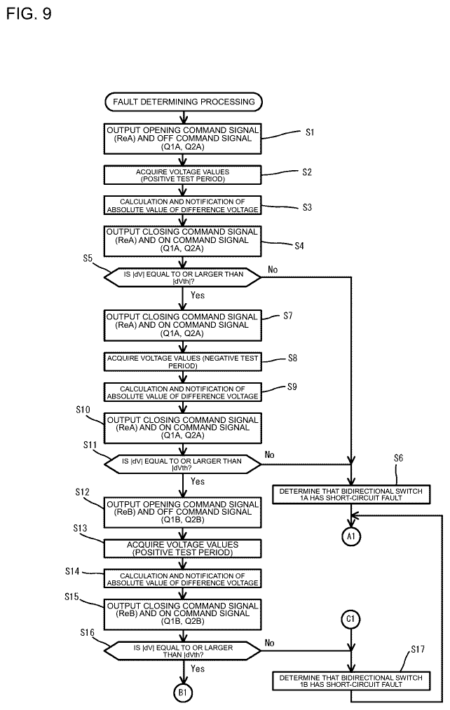

Next, the fault determining processing performed by the determination unit 304 according to the present preferred embodiment is described with reference to FIGS. 9 to 13. Note that it is assumed that at the start of the fault determining processing, all of the relays ReA, ReB, ReC, and ReD of the bidirectional switches 1A, 1B, 1C, and 1D are in a closed state and all of the switching elements Q1A, Q2A, Q1B, Q2B, Q1C, Q2C, Q1D, and Q2D are in an ON state. As illustrated in FIG. 9, first, the command unit 301 outputs an opening command signal to the relay ReA and outputs an OFF command signal to the switching elements Q1A and Q2A by referring to test case information corresponding to the identification information IDT[0] stored in the test case storage 331 upon notification of test period start notification information of a test period of a positive polarity from the voltage acquisition unit 302 (step S1). The command unit 301 maintains the relays ReB, ReC, and ReD in a closed state and maintains the switching elements Q1B, Q2B, Q1C, Q2C, Q1D, and Q2D in an ON state. Next, the voltage acquisition unit 302 acquires a voltage value measured by the voltmeter 12A and a voltage value measured by the voltmeter 13A during the test period of the positive polarity (step S2). To “acquire a voltage value” means converting a measurement signal input from the voltmeter 12A or 13A into voltage value information. The same applies hereinafter. Subsequently, the difference calculation unit 303 calculates an absolute value of a difference voltage between the voltage value measured by the voltmeter 12A and the voltage value measured by the voltmeter 13A and notifies the determination unit 304 of the calculated absolute value of the difference voltage (step S3). Then, the command unit 301 outputs a closing command signal to the relay ReA and outputs an ON command signal to the switching elements Q1A and Q2A upon notification of test period end notification information from the voltage acquisition unit 302 (step S4). Next, the determination unit 304 determines whether or not the absolute value |dV| of the difference voltage indicated by the difference voltage information received from the difference calculation unit 303 is equal to or larger than a difference voltage threshold value |dVth| (step S5). In a case where the determination unit 304 determines that the absolute value |dV| of the difference voltage is smaller than the difference voltage threshold value |dVth| (step S5: No), the determination unit 304 determines that the bidirectional switch 1A has a short-circuit fault (step S6), and the fault determining processing is finished.

On the other hand, assume that the determination unit 304 determines that the absolute value |dV| of the difference voltage is equal to or larger than the difference voltage threshold value |dVth| (step S5: Yes). In this case, the command unit 301 outputs an opening command signal to the relay ReA and outputs an OFF command signal to the switching elements Q1A and Q2A again upon notification of test period start notification information of a test period of a negative polarity from the voltage acquisition unit 302 (step S7). The command unit 301 maintains the relays ReB, ReC, and ReD in a closed state and maintains the switching elements Q1B, Q2B, Q1C, Q2C, Q1D, and Q2D in an ON state. Subsequently, the voltage acquisition unit 302 acquires a voltage value measured by the voltmeter 12A and a voltage value measured by the voltmeter 13A during the test period of the negative polarity (step S8). Then, the difference calculation unit 303 calculates an absolute value of a difference voltage between the voltage value measured by the voltmeter 12A and the voltage value measured by the voltmeter 13A and notifies the determination unit 304 of the calculated absolute value of the difference voltage (step S9). Next, the command unit 301 outputs a closing command signal to the relay ReA and outputs an ON command signal to the switching elements Q1A and Q2A upon notification of test period end notification information from the voltage acquisition unit 302 (step S10). Subsequently, the determination unit 304 determines whether or not the absolute value |dV| of the difference voltage indicated by the difference voltage information received from the difference calculation unit 303 is equal to or larger than the difference voltage threshold value |dVth| (step S11). In a case where the determination unit 304 determines that the absolute value |dV| of the difference voltage is smaller than the difference voltage threshold value |dVth| (step S11: No), the determination unit 304 determines that the bidirectional switch 1A has a short-circuit fault (step S6), and the fault determining processing is finished.

On the other hand, assume that the determination unit 304 determines that the absolute value |dV| of the difference voltage is equal to or larger than the difference voltage threshold value |dVth| (step S11: Yes). In this case, the command unit 301 outputs an opening command signal to the relay ReB and outputs an OFF command signal to the switching elements Q1B and Q2B by referring to test case information corresponding to the identification information IDT[1] stored in the test case storage 331 upon notification of test period start notification information of a test period of a positive polarity from the voltage acquisition unit 302 (step S12). The command unit 301 maintains the relays ReA, ReC, and ReD in a closed state and maintains the switching elements Q1A, Q2A, Q1C, Q2C, Q1D, and Q2D in an ON state. Then, the voltage acquisition unit 302 acquires a voltage value measured by the voltmeter 12B and a voltage value measured by the voltmeter 13B during the test period of the positive polarity (step S13). Next, the difference calculation unit 303 calculates an absolute value of a difference voltage between the voltage value measured by the voltmeter 12B and the voltage value measured by the voltmeter 13B and notifies the determination unit 304 of the calculated absolute value of the difference voltage (step S14). Subsequently, the command unit 301 outputs a closing command signal to the relay ReB and outputs an ON command signal to the switching elements Q1B and Q2B upon notification of test period end notification information from the voltage acquisition unit 302 (step S15). Then, the determination unit 304 determines whether or not the absolute value |dV| of the difference voltage indicated by the difference voltage information received from the difference calculation unit 303 is equal to or larger than the difference voltage threshold value |dVth| (step S16). In a case where the determination unit 304 determines that the absolute value |dV| of the difference voltage is smaller than the difference voltage threshold value |dVth| (step S16: No), the determination unit 304 determines that the bidirectional switch 1B has a short-circuit fault (step S17), and the fault determining processing is finished.

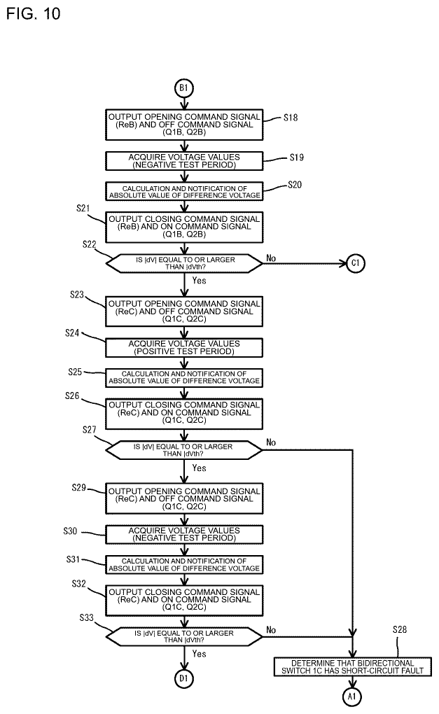

On the other hand, assume that the determination unit 304 determines that the absolute value |dV| of the difference voltage is equal to or larger than the difference voltage threshold value |dVth| (step S16: Yes). In this case, as illustrated in FIG. 10, the command unit 301 outputs an opening command signal to the relay ReB and outputs an OFF command signal to the switching elements Q1B and Q2B again upon notification of test period start notification information of a test period of a negative polarity from the voltage acquisition unit 302 (step S18). Next, the voltage acquisition unit 302 acquires a voltage value measured by the voltmeter 12B and a voltage value measured by the voltmeter 13B during the test period of the negative polarity (step S19). Subsequently, the difference calculation unit 303 calculates an absolute value of a difference voltage between the voltage value measured by the voltmeter 12B and the voltage value measured by the voltmeter 13B and notifies the determination unit 304 of the calculated absolute value of the difference voltage (step S20). Then, the command unit 301 outputs a closing command signal to the relay ReB and outputs an ON command signal to the switching elements Q1B and Q2B upon notification of test period end notification information from the voltage acquisition unit 302 (step S21). Next, the determination unit 304 determines whether or not the absolute value |dV| of the difference voltage indicated by the difference voltage information received from the difference calculation unit 303 is equal to or larger than the difference voltage threshold value |dVth| (step S22). In a case where the determination unit 304 determines that the absolute value |dV| of the difference voltage is smaller than the difference voltage threshold value |dVth| (step S22: No), the determination unit 304 determines that the bidirectional switch 1B has a short-circuit fault (step S17) as illustrated in FIG. 9, and the fault determining processing is finished.

On the other hand, assume that the determination unit 304 determines that the absolute value |dV| of the difference voltage is equal to or larger than the difference voltage threshold value |dVth| (step S22: Yes), as illustrated in FIG. 10. In this case, the command unit 301 outputs an opening command signal to the relay ReC and outputs an OFF command signal to the switching elements Q1C and Q2C by referring to test case information corresponding to the identification information IDT[2] stored in the test case storage 331 upon notification of test period start notification information of a test period of a positive polarity from the voltage acquisition unit 302 (step S23). The command unit 301 maintains the relays ReA, ReB, and ReD in a closed state and maintains the switching elements Q1A, Q2A, Q1B, Q2B, Q1D, and Q2D in an ON state. Then, the voltage acquisition unit 302 acquires a voltage value measured by the voltmeter 12C and a voltage value measured by the voltmeter 13C during the test period of the positive polarity (step S24). Next, the difference calculation unit 303 calculates an absolute value of a difference voltage between the voltage value measured by the voltmeter 12C and the voltage value measured by the voltmeter 13C and notifies the determination unit 304 of the calculated absolute value of the difference voltage (step S25). Subsequently, the command unit 301 outputs a closing command signal to the relay ReC and outputs an ON command signal to the switching elements Q1C and Q2C upon notification of test period end notification information from the voltage acquisition unit 302 (step S26). Then, the determination unit 304 determines that the absolute value |dV| of the difference voltage indicated by the difference voltage information received from the difference calculation unit 303 is equal to or larger than the difference voltage threshold value |dVth| (step S27). In case where the determination unit 304 determines that the absolute value |dV| of the difference voltage is smaller than the difference voltage threshold value |dVth| (step S27: No), the determination unit 304 determines that the bidirectional switch 1C has a short-circuit fault (step S28), and the fault determining processing is finished.

On the other hand, assume that the determination unit 304 determines that the absolute value |dV| of the difference voltage is equal to or larger than the difference voltage threshold value |dVth| (step S27: Yes). In this case, the command unit 301 outputs an opening command signal to the relay ReC and outputs an OFF command signal to the switching elements Q1C and Q2C again upon notification of test period start notification information of a test period of a negative polarity from the voltage acquisition unit 302 (step S29). Next, the voltage acquisition unit 302 acquires a voltage value measured by the voltmeter 12C and a voltage value measured by the voltmeter 13C during the test period of the negative polarity (step S30). Subsequently, the difference calculation unit 303 calculates an absolute value of a difference voltage between the voltage value measured by the voltmeter 12C and the voltage value measured by the voltmeter 13C and notifies the determination unit 304 of the calculated absolute value of the difference voltage (step S31). Then, the command unit 301 outputs a closing command signal to the relay ReC and outputs an ON command signal to the switching elements Q1C and Q2C upon notification of test period end notification information from the voltage acquisition unit 302 (step S32). Next, the determination unit 304 determines whether or not the absolute value |dV| of the difference voltage indicated by the difference voltage information received from the difference calculation unit 303 is equal to or larger than the difference voltage threshold value |dVth| (step S33). In a case where the determination unit 304 determines that the absolute value |dV| of the difference voltage is smaller than the difference voltage threshold value |dVth| (step S33: No), the determination unit 304 determines that the bidirectional switch 1C has a short-circuit fault (step S28), and the fault determining processing is finished.

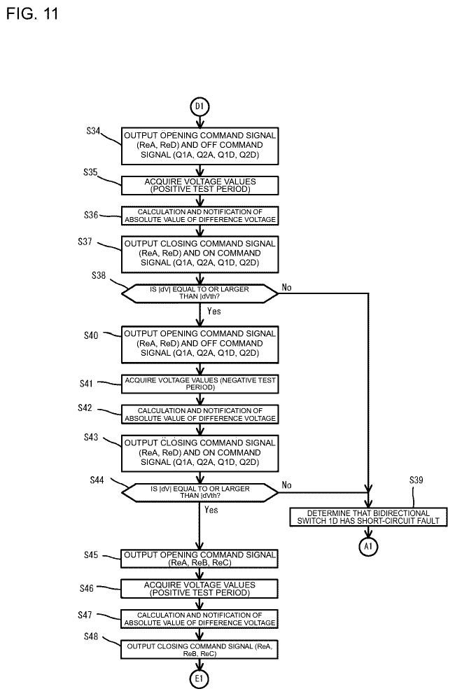

On the other hand, assume that the determination unit 304 determines that the absolute value |dV| of the difference voltage is equal to or larger than the difference voltage threshold value |dVth| (step S33: Yes). In this case, as illustrated in FIG. 11, the command unit 301 outputs an opening command signal to the relays ReA and ReD and outputs an OFF command signal to the switching elements Q1A, Q2A, Q1D, and Q2D by referring to test case information corresponding to the identification information IDT[3] stored in the test case storage 331 upon notification of test period start notification information of a test period of a positive polarity from the voltage acquisition unit 302 (step S34). The command unit 301 maintains the relays ReB and ReC in a closed state and maintains the switching elements Q1B, Q2B, Q1C, and Q2C in an ON state. Then, the voltage acquisition unit 302 acquires a voltage value measured by the voltmeter 12B and a voltage value measured by the voltmeter 13B during the test period of the positive polarity (step S35). Next, the difference calculation unit 303 calculates an absolute value of a difference voltage between the voltage value measured by the voltmeter 12B and the voltage value measured by the voltmeter 13B and notifies the determination unit 304 of the calculated absolute value of the difference voltage (step S36). Subsequently, the command unit 301 outputs a closing command signal to the relays ReA and ReD and outputs an ON command signal to the switching elements Q1A, Q2A, Q1D, and Q2D upon notification of test period end notification information from the voltage acquisition unit 302 (step S37). Then, the determination unit 304 determines whether or not the absolute value |dV| of the difference voltage indicated by the difference voltage information received from the difference calculation unit 303 is equal to or larger than the difference voltage threshold value |dVth| (step S38). In a case where the determination unit 304 determines that the absolute value |dV| of the difference voltage is smaller than the difference voltage threshold value |dVth| (step S38: No), the determination unit 304 determines that the bidirectional switch 1D has a short-circuit fault (step S39), and the fault determining processing is finished.

On the other hand, assume that the determination unit 304 determines that the absolute value |dV| of the difference voltage is equal to or larger than the difference voltage threshold value |dVth| (step S38: Yes). In this case, the command unit 301 outputs an opening command signal to the relays ReA and ReD and outputs an OFF command signal to the switching elements Q1A, Q2A, Q1D, and Q2D again upon notification of test period start notification information of a test period of a negative polarity from the voltage acquisition unit 302 (step S40). Next, the voltage acquisition unit 302 acquires a voltage value measured by the voltmeter 12B and a voltage value measured by the voltmeter 13B during the test period of the negative polarity (step S41). Subsequently, the difference calculation unit 303 calculates an absolute value of a difference voltage between the voltage value measured by the voltmeter 12B and the voltage value measured by the voltmeter 13B and notifies the determination unit 304 of the calculated absolute value of the difference voltage (step S42). Then, the command unit 301 outputs a closing command signal to the relays ReA and ReD and outputs an ON command signal to the switching elements Q1A, Q2A, Q1D, and Q2D upon notification of test period end notification information from the voltage acquisition unit 302 (step S43). Next, the determination unit 304 determines whether or not the absolute value |dV| of the difference voltage indicated by the difference voltage information received from the difference calculation unit 303 is equal to or larger than the difference voltage threshold value |dVth| (step S44). In a case where the determination unit 304 determines that the absolute value |dV| of the difference voltage is smaller than the difference voltage threshold value |dVth| (step S44: No), the determination unit 304 determines that the bidirectional switch 1D has a short-circuit fault (step S39), and the fault determining processing is finished.

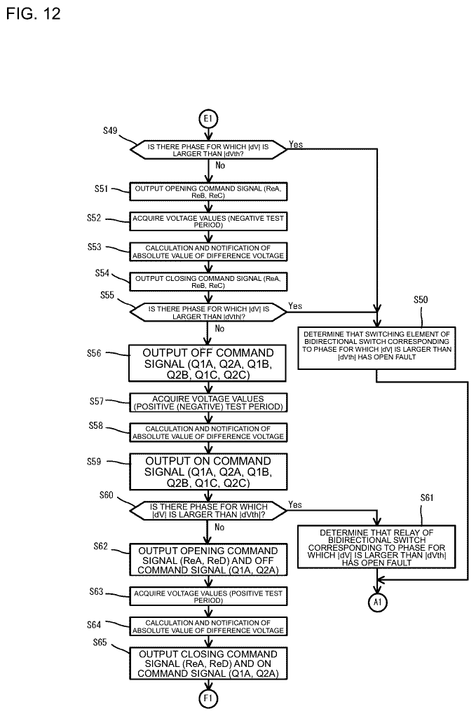

On the other hand, assume that the determination unit 304 determines that the absolute value |dV| of the difference voltage is equal to or larger than the difference voltage threshold value |dVth| (step S44: Yes). In this case, the command unit 301 outputs an opening command signal to the relays ReA, ReB, and ReC by referring to test case information corresponding to the identification information IDT[4] stored in the test case storage 331 upon notification of test period start notification information of a test period of a positive polarity from the voltage acquisition unit 302 (step S45). The command unit 301 maintains the relay ReD in a closed state and maintains the switching elements Q1A, Q2A, Q1B, Q2B, Q1C, Q2C, Q1D, and Q2D in Then, the voltage acquisition unit 302 acquires an ON state. Then, the voltage acquisition unit 302 acquires voltage values measured by the voltmeters 12A, 12B, and 12C and voltage values measured by the voltmeters 13A, 13B, and 13C during the test period of the positive polarity (step S46). Next, the difference calculation unit 303 calculates absolute values of difference voltages between the voltage values measured by the voltmeters 12A, 12B, and 12C and the voltage values measured by the voltmeters 13A, 13B, and 13C and notifies the determination unit 304 of the calculated absolute values of the difference voltages (step S47). Subsequently, the command unit 301 outputs a closing command signal to the relays ReA, ReB, and ReC upon notification of test period end notification information from the voltage acquisition unit 302 (step S48). Then, as illustrated in FIG. 12, the determination unit 304 determines whether or not there is a phase for which the absolute value |dV| of the difference voltage indicated by the difference voltage information received from the difference calculation unit 303 is larger than the difference voltage threshold value |dVth| (step S49). Assume that the determination unit 304 determines that there is a phase for which the absolute value |dV| of the difference voltage is larger than the difference voltage threshold value |dVth| (step S49: Yes). In this case, the determination unit 304 determines that the switching elements Q1A and Q2A (Q1B and Q2B, Q1C and Q2C) of the bidirectional switch 1A (1B, 1C) corresponding to the phase for which the absolute value |dV| of the difference voltage is larger than the difference voltage threshold value |dVth| have an open fault (step S50), and the fault determining processing is finished.

On the other hand, assume that the determination unit 304 determines that the absolute value |dV| of the difference voltage is equal to or smaller than the difference voltage threshold value |dVth| for all phases (step S49: No). In this case, the command unit 301 outputs an opening command signal to the relays ReA, ReB, and ReC by referring to test case information corresponding to the identification information IDT[5] stored in the test case storage 331 upon notification of test period start notification information of a test period of a negative polarity from the voltage acquisition unit 302 (step S51). The command unit 301 outputs an ON command signal to the switching elements Q1A, Q2A, Q1B, Q2B, Q1C, and Q2C. The command unit 301 maintains the relay ReD in a closed state and maintains the switching elements Q1A, Q2A, Q1B, Q2B, Q1C, Q2C, Q1D, and Q2D in an ON state. Next, the voltage acquisition unit 302 acquires voltage values measured by the voltmeters 12A, 12B, and 12C and voltage values measured by the voltmeters 13A, 13B, and 13C during the test period of the negative polarity (step S52). Subsequently, the difference calculation unit 303 calculates absolute values of difference voltages between the voltage values measured by the voltmeters 12A, 12B, and 12C and voltage values measured by the voltmeters 13A, 13B, and 13C and notifies the determination unit 304 of the calculated absolute values of the difference voltages (step S53). Then, the command unit 301 outputs a closing command signal to the relays ReA, ReB, and ReC upon notification of test period end notification information from the voltage acquisition unit 302 (step S54). Next, the determination unit 304 determines whether or not there is a phase for which the absolute value |dV| of the difference voltage indicated by the difference voltage information received from the difference calculation unit 303 is larger than the difference voltage threshold value |dVth| (step S55). Assume that the determination unit 304 determines that there is a phase for which the absolute value |dV| of the difference voltage is larger than the difference voltage threshold value |dVth| (step S55: Yes). In this case, the determination unit 304 determines that the switching elements Q1A and Q2A (Q1B and Q2B, Q1C and Q2C) of the bidirectional switch 1A (1B, 1C) corresponding to the phase for which the absolute value |dV| of the difference voltage is larger than the difference voltage threshold value |dVth| have an open fault (step S50), and the fault determining processing is finished.

On the other hand, assume that the determination unit 304 determines that the absolute value |dV| of the difference voltage is equal to or smaller than the difference voltage threshold value |dVth| for all phases (step S55: No). In this case, the command unit 301 outputs an OFF command signal to the switching elements Q1A, Q2A, Q1B, Q2B, Q1C, and Q2C by referring to test case information corresponding to the identification information IDT[6] stored in the test case storage 331 upon notification of test period start notification information of a test period of a positive polarity or a test period of a negative polarity from the voltage acquisition unit 302 (step S56). The command unit 301 outputs a closing command signal to the relays ReA, ReB, and ReC. The command unit 301 maintains the relay ReD in a closed state and maintains the switching elements Q1D and Q2D in an ON state. Then, the voltage acquisition unit 302 acquires voltage values measured by the voltmeters 12A, 12B, and 12C and voltage values measured by the voltmeters 13A, 13B, and 13C during the test period of the positive polarity or the test period of the negative polarity (step S57). Subsequently, the difference calculation unit 303 calculates absolute values of difference voltages between the voltage values measured by the voltmeters 12A, 12B, and 12C and voltage values measured by the voltmeters 13A, 13B, and 13C and notifies the determination unit 304 of the calculated absolute values of the difference voltages (step S58). Then, the command unit 301 outputs an ON command signal to the switching elements Q1A, Q2A, Q1B, Q2B, Q1C, and Q2C upon notification of test period end notification information from the voltage acquisition unit 302 (step S59). Then, the determination unit 304 determines whether or not there is a phase for which the absolute value |dV| of the difference voltage indicated by the difference voltage information received from the difference calculation unit 303 is larger than the difference voltage threshold value |dVth| (step S60). Assume that the determination unit 304 determines that there is a phase for which the absolute value |dV| of the difference voltage is larger than the difference voltage threshold value |dVth| (step S60: Yes). In this case, the determination unit 304 determines that the relay ReA (ReB, ReC) of the bidirectional switch 1A (1B, 1C) corresponding to the phase for which the absolute value |dV| of the difference voltage is larger than the difference voltage threshold value |dVth| has an open fault (step S61), and the fault determining processing is finished.

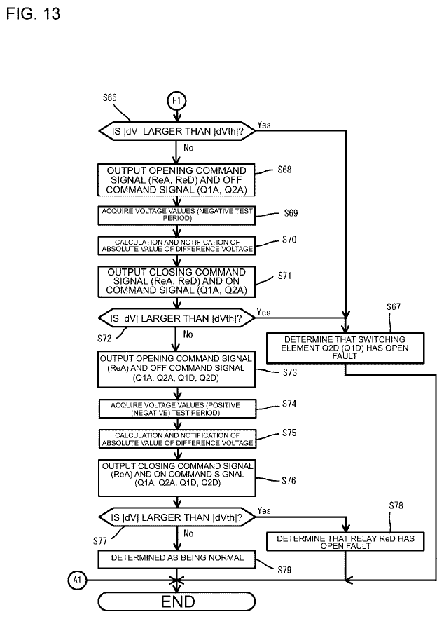

On the other hand, assume that the determination unit 304 determines that the absolute value |dV| of the difference voltage is equal to or smaller than the difference voltage threshold value |dVth| for all phases (step S60: No). In this case, the command unit 301 outputs an opening command signal to the relays ReA and ReD and outputs an OFF command signal to the switching elements Q1A and Q2A by referring to test case information corresponding to the identification information IDT[7] stored in the test case storage 331 upon notification of test period start notification information of a test period of a positive polarity from the voltage acquisition unit 302 (step S62). The command unit 301 outputs an ON command signal to the switching elements Q1D and Q2D. The command unit 301 maintains the relays ReB and ReC in a closed state and maintains the switching elements Q1B, Q2B, Q1C, and Q2C in an ON state. Next, the voltage acquisition unit 302 acquires a voltage value measured by the voltmeter 12B and a voltage value measured by the voltmeter 13B during the test period of the positive polarity (step S63). Next, the difference calculation unit 303 calculates an absolute value of a difference voltage between the voltage value measured by the voltmeter 12B and the voltage value measured by the voltmeter 13B and notifies the determination unit 304 of the calculated absolute value of the difference voltage (step S64). Then, the command unit 301 outputs a closing command signal to the relays ReA and ReD and outputs an ON command signal to the switching elements Q1A and Q2A upon notification of test period end notification information from the voltage acquisition unit 302 (step S65). Next, as illustrated in FIG. 13, the determination unit 304 determines whether or not the absolute value |dV| of the difference voltage indicated by the difference voltage information received from the difference calculation unit 303 is larger than the difference voltage threshold value |dVth| (step S66). In a case where the determination unit 304 determines that the absolute value |dV| of the difference voltage is larger than the difference voltage threshold value |dVth| (step S66: Yes), the determination unit 304 determines that the switching element Q2D has an open fault (step S67), and the fault determining processing is finished.

On the other hand, assume that the determination unit 304 determines that the absolute value |dV| of the difference voltage is equal to or smaller than the difference voltage threshold value |dVth| (step S66: No). In this case, the command unit 301 outputs an opening command signal to the relays ReA and ReD and outputs an OFF command signal to the switching elements Q1A and Q2A again upon notification of test period start notification information of a test period of a negative polarity from the voltage acquisition unit 302 (step S68). The command unit 301 outputs an ON command signal to the switching elements Q1D and Q2D. The command unit 301 maintains the relays ReB and ReC in a closed state and maintains the switching elements Q1B, Q2B, Q1C, and Q2C in an ON state. Subsequently, the voltage acquisition unit 302 acquires a voltage value measured by the voltmeter 12B and a voltage value measured by the voltmeter 13B during the test period of the negative polarity (step S69). Then, the difference calculation unit 303 calculates an absolute value of a difference voltage between the voltage value measured by the voltmeter 12B and the voltage value measured by the voltmeter 13B and notifies the determination unit 304 of the calculated absolute value of the difference voltage (step S70). Next, the command unit 301 outputs a closing command signal to the relays ReA and ReD and outputs an ON command signal to the switching elements Q1A and Q2A upon notification of test period end notification information from the voltage acquisition unit 302 (step S71). Subsequently, the determination unit 304 determines whether or not the absolute value |dV| of the difference voltage indicated by the difference voltage information received from the difference calculation unit 303 is larger than the difference voltage threshold value |dVth| (step S72). In a case where the determination unit 304 determines that the absolute value |dV| of the difference voltage is larger than the difference voltage threshold value |dVth| (step S72: Yes), the determination unit 304 determines that the switching element Q1D has an open fault (step S67), and the fault determining processing is finished.

On the other hand, assume that the determination unit 304 determines that the absolute value |dV| of the difference voltage is equal to or smaller than the difference voltage threshold value |dVth| (step S72: No). In this case, the command unit 301 outputs an opening command signal to the relay ReA and outputs an OFF command signal to the switching elements Q1A, Q2A, Q1D, and Q2D upon notification of test period start notification information of a test period of a positive polarity or a test period of a negative polarity from the voltage acquisition unit 302 (step S73). The command unit 301 outputs a closing command signal to the relay ReD. The command unit 301 maintains the relays ReB and ReC in a closed state and maintains the switching elements Q1B, Q2B, Q1C, and Q2C in an ON state. Then, the voltage acquisition unit 302 acquires a voltage value measured by the voltmeter 12B and a voltage value measured by the voltmeter 13B during the test period of the positive polarity or the test period of the negative polarity (step S74). Next, the difference calculation unit 303 calculates an absolute value of a difference voltage between the voltage value measured by the voltmeter 12B and the voltage value measured by the voltmeter 13B and notifies the determination unit 304 of the calculated absolute value of the difference voltage (step S75). Subsequently, the command unit 301 outputs a closing command signal to the relay ReA and outputs an ON command signal to the switching elements Q1A, Q2A, Q1D, and Q2D upon notification of test period end notification information from the voltage acquisition unit 302 (step S76). Subsequently, the determination unit 304 determines whether or not the absolute value |dV| of the difference voltage indicated by the difference voltage information received from the difference calculation unit 303 is larger than the difference voltage threshold value |dVth| (step S77). In a case where the determination unit 304 determines that the absolute value |dV| of the difference voltage is larger than the difference voltage threshold value |dVth| (step S77: Yes), the determination unit 304 determines that the relay ReD has an open fault (step S78), and the fault determining processing is finished. On the other hand, in a case where the determination unit 304 determines that the absolute value |dV| of the difference voltage is equal to or smaller than the difference voltage threshold value |dVth| (step S77: No), the determination unit 304 determines that all of the bidirectional switches 1A, 1B, 1C, and 1D have no fault and are normal (step S79), and the fault determining processing is finished.

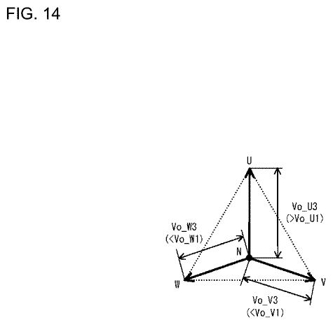

It is assumed that, in a configuration similar to the switching module 501 according to the present preferred embodiment, only the bidirectional switch 1D is in an opened state and the other bidirectional switches 1A, 1B, and 1C are in a closed state. In this case, for example, it is assumed that impedances of the power conversion circuits 201 and 204 connected to the U-phase output terminal te3A are larger than impedances of the power conversion circuits 202, 203, 205, and 206 connected to the V-phase and W-phase output terminals te3B and te3C. In this case, as illustrated in FIG. 14, a voltage amplitude Vo_U3 of a voltage measured by the voltmeter 13A is larger than voltage amplitudes Vo_V3 and Vo_W3 of voltages measured by the voltmeters 13B and 13C. It is therefore possible to determine whether or not the bidirectional switch 1D has a fault on the basis of absolute values of difference voltages between voltages measured by the voltmeters 12A, 12B, and 12C and voltages measured by the voltmeters 13A, 13B, and 13C. However, in a case where impedances of the power conversion circuits 201, 202, 203, 204, 205, and 206 connected to the U-phase output terminal te3A, the V-phase output terminal te3B, and the W-phase output terminal te3C are equal to each other, the voltage amplitudes Vo_U3, Vo_V3, and Vo_W3 of the voltages measured by the voltmeters 13A, 13B, and 13C are equal to each other, and are equal to the voltage amplitudes Vo_U1, Vo_V1, and Vo_W1 of the voltages measured by the voltmeters 12A, 12B, and 12C. Therefore, the absolute values of the difference voltages do not change irrespective of an opened or closed state of the bidirectional switch 1D, and it is therefore impossible to determine whether or not the bidirectional switch 1D has a fault.

On the other hand, according to the switching module 501 according to the present preferred embodiment, the command unit 301 outputs an opening command signal to the relays ReA and ReD and outputs a closing command signal to the relays ReB and ReC. In a case where an absolute value of a difference voltage between a voltage measured by the voltmeter 12B and a voltage measured by the voltmeter 13B is equal to or smaller than a difference voltage threshold value in this state, the determination unit 304 determines that at least one of the relays ReA and ReD has a short-circuit fault. Therefore, even in a case where impedances of the power conversion circuits 201, 202, 203, 204, 205, and 206 connected to the output terminals te3A, te3B, and te3C are equal, it is possible to determine whether or not the relay ReD has a fault, and therefore it is possible to detect the presence or absence of a fault for all of the relays ReA, ReB, ReC, and ReD included in the switching module 501.

Furthermore, the determination unit 304 according to the present preferred embodiment determines that the relay ReA has a short-circuit fault in a case where an absolute value of a difference voltage between voltage values measured by the voltmeters 12A and 13A is equal to or smaller than the difference voltage threshold value in a state where the command unit 301 outputs an opening command signal to the relay ReA and outputs a closing command signal to the relays ReB, ReC, and ReD. The determination unit 304 determines whether or not the relays ReB and ReC have a short-circuit fault in a similar manner. In this way, it is possible to determine whether or not the relays ReA, ReB, and ReC have a short-circuit fault.

Furthermore, in a case where the switching elements Q1A, Q2A, Q1B, Q2B, Q1C, and Q2C include a switching element for which the absolute value of the difference voltage is larger than the difference voltage threshold value in a state where the relays ReA, ReB, and ReC are in an opened state and the command unit 301 outputs an ON command signal to the switching elements Q1A, Q2A, Q1B, Q2B, Q1C, Q2C, Q1D, and Q2D, the determination unit 304 according to the present preferred embodiment determines that the switching element has an open fault. In this way, it is possible to determine whether or not the switching elements Q1A, Q2A, Q1B, Q2B, Q1C, and Q2C have an open fault.

In a case where the relays ReA, ReB, and ReC include a relay for which the absolute value of the difference voltage is larger than the difference voltage threshold value in a state where the switching elements Q1A, Q2A, Q1B, Q2B, Q1C, and Q2C are in an ON state and the command unit 301 outputs a closing command signal to the relays ReA, ReB, and ReC, the determination unit 304 according to the present preferred embodiment determines that the relay has an open fault. In this way, it is possible to determine whether or not the relays ReA, ReB, and ReC have an open fault.

Furthermore, in a case where the absolute value of the difference voltage is larger than the difference voltage threshold value as for the switching elements Q1D and Q2D in a state where the relays ReA, ReB, and ReC are in a closed state and the relay ReD is in an opened state and the command unit 301 outputs an ON command signal to the switching elements Q1D and Q2D, the determination unit 304 according to the present preferred embodiment determines that the switching elements Q1D and Q2D have an open fault. In this way, it is possible to determine whether or not the switching elements Q1D and Q2D have an open fault.

For example, assume that the power wire L1D of the module body 100A and the power wire L2D of the module body 100B are connected to a common grounding wire. In this case, in a case where a short-circuit fault occurs in the bidirectional switch 1D, the bidirectional switches of the module body 100B may be shifted to a closed state without stopping output of the alternating-current power source PA1, as long as the bidirectional switches 1A, 1B, and 1C are in an opened state. On the other hand, in a case where a short-circuit fault occurs in any of the bidirectional switches 1A, 1B, and 1C, shifting the bidirectional switches of the module body 100B into a closed state without stopping output of the alternating-current power source PA1 may undesirably cause a wire of the module body 100B and the power wire L1A (L1B, L1C) connected to the bidirectional switch 1A (1B, 1C) having the short-circuit fault to be short-circuited, leading to a risk of flow of a large current through the module body 100B. On the other hand, the switching module 501 according to the present preferred embodiment can determine whether a short-circuit fault is occurring in any of the bidirectional switches 1A, 1B, and 1C or occurring in the bidirectional switch 1D by performing the fault determining processing, and therefore can properly switch a used module body between the module bodies 100A and 100B.

In a case where the relays ReA, ReB, ReC, and ReD have an open fault, it is sometimes required to continue use while restricting a current flowing through the switching elements Q1A, Q2A, Q1B, Q2B, Q1C, Q2C, Q1D, and Q2D connected in parallel with the relays ReA, ReB, ReC, and ReD. In this respect, the switching module 501 according to the present preferred embodiment can determine whether or not an open fault is occurring in any of the switching elements Q1A, Q2A, Q1B, Q2B, Q1C, Q2C, Q1D, and Q2D by performing the fault determining processing, and therefore can properly determine whether or not to continue use of the module body 100A or 100B.

### Preferred Embodiment 2

A switching module according to the present preferred embodiment is different from that of Preferred Embodiment 1 in that the switching module according to the present preferred embodiment is used while being connected to a single-phase three-wire alternating-current power source including two polar terminals that output phase voltages and a neutral terminal.

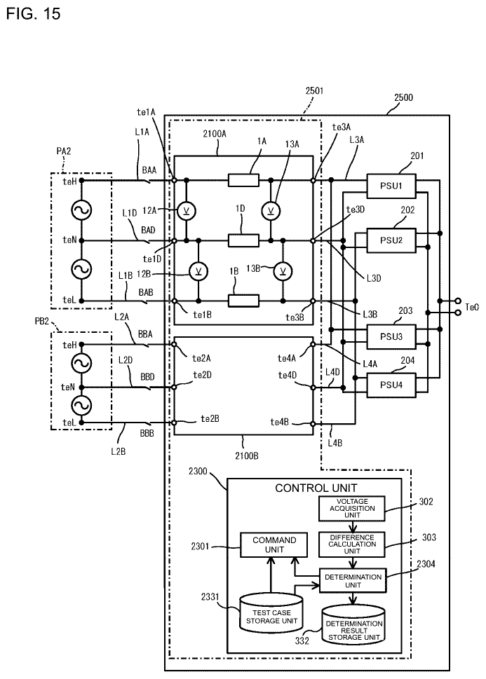

For example, as illustrated in FIG. 15, a power source system 2500 according to the present preferred embodiment receives alternating-current power from an alternating-current power source PA2 or a standby alternating-current power source PB2 and supplies direct-current power to a load such as a server (not illustrated) connected to an output terminal TeO. In FIG. 15, constituent elements similar to those in Preferred Embodiment 1 are given reference signs identical to those in FIG. 1. The alternating-current power source PA2 includes two polar terminals teH and teL and a neutral terminal teN. The alternating-current power source PA2 supplies an alternating current to the power source system 2500 through three power wires L1A, L1B, and L1D that are connected to the polar terminals teH and teL and the neutral terminal teN, respectively. The alternating-current power source PB also has two polar terminals teH and teL and a neutral terminal teN. The alternating-current power source PB also supplies an alternating current to the power source system 2500 through three power wires L2A, L2B, and L2D that are connected to the polar terminals teH and teL and the neutral terminal teN, respectively. Furthermore, breakers BAA, BAB, BAD, BBA, BBB, and BBD are provided on the power wires L1A, L1B, L1D, L2A, L2B, and L2D, respectively.

The power source system 2500 includes four power conversion circuits 201, 202, 203, and 204 and a switching module 2501. The switching module 2501 includes two module bodies 2100A and 2100B and a controller 2300 configured or programmed to control operation of the module bodies 2100A and 2100B. The module body 2100A includes input terminals te1A, te1B, and te1D and output terminals te3A, te3B, and te3D. The input terminals te1A, te1B, and te1D are connected to power wires L1A, L1B, and L1D connected to the alternating-current power source PA2, respectively. The output terminals te3A, te3B, and te3D are connected to power wires L3A, L3B, and L3D connected to the power conversion circuits 201, 202, 203, and 204. The module body 2100B also includes input terminals te2A, te2B, and te2D and output terminals te4A, te4B, and te4D. The input terminals te2A, te2B, and te2D are connected to power wires L2A, L2B, and L2D connected to the standby alternating-current power source PB2, respectively. The output terminals te4A, te4B, and te4D are connected to power wires L4A, L4B, and L4D connected to the power conversion circuits 201, 202, 203, and 204. The module body 2100A includes three bidirectional switches 1A, 1B, and 1D and four voltmeters 12A, 12B, 13A, and 13B. The module body 2100B also has a similar configuration to the module body 100A, and includes three bidirectional switches (not illustrated) and four voltmeters (not illustrated).

The bidirectional switch 1A (1B) includes a single relay ReA (ReB) and two switching elements Q1A and Q2A (Q1B and Q2B), as described by using FIG. 3 in Preferred Embodiment 1. The bidirectional switch 1D also includes a single relay ReD and two switching elements Q1D and Q2D. The voltmeter 12A is connected between an input end I1A of the bidirectional switch 1A and an input end I1D of the bidirectional switch 1D, and the voltmeter 12B is connected between an input end I1B of the bidirectional switch 1B and the input end I1D of the bidirectional switch 1D. The voltmeter 13A is connected between an output end O1A of the bidirectional switch 1A and an output end O1D of the bidirectional switch 1D, and the voltmeter 13B is connected between an output end O1B of the bidirectional switch 1B and the output end O1D of the bidirectional switch 1D.

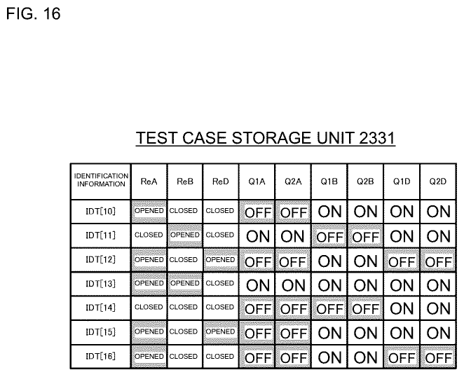

The controller 2300 has a similar hardware configuration to the controller 300 according to Preferred Embodiment 1 and is configured or programmed to control operation of the module bodies 2100A and 2100B. The controller 2300 is configured or programmed to include a command unit 2301, a voltage acquisition unit 302, a difference calculation unit 303, and a determination unit 2304. A memory includes a determination result storage 332 and a test case storage 2331, as in Preferred Embodiment 1. The test case storage 2331 stores therein seven pieces of test case information indicative of combinations of opened or closed states of the relays ReA, ReB, and ReD of the bidirectional switches 1A, 1B, and 1D and ON or OFF states of the switching elements Q1A, Q2A, Q1B, Q2B, Q1D, and Q2D in association with identification information IDT[10], IDT[11], . . . , IDT[16], for example, as illustrated in FIG. 16.

The command unit 2301 controls opened or closed states of the relays ReA, ReB, and ReD by separately outputting opening command signals to shift the relays ReA, ReB, and ReD into an opened state or closing command signals to shift the relays ReA, ReB, and ReD into a closed state to the relays ReA, ReB, and ReD. Furthermore, the command unit 2301 controls ON or OFF states of the switching elements Q1A, Q2A, Q1B, Q2B, Q1D, and Q2D by separately outputting ON command signals to shift the switching elements Q1A, Q2A, Q1B, Q2B, Q1D, and Q2D into an ON state or OFF command signals to shift the switching elements Q1A, Q2A, Q1B, Q2B, Q1D, and Q2D into an OFF state to the switching elements Q1A, Q2A, Q1B, Q2B, Q1D, and Q2D.

The determination unit 2304 determines whether or not the bidirectional switches 1A, 1B, and 1D have a fault by performing fault determining processing, which will be described later. In a case where the determination unit 2304 determines whether or not the relay ReA of the bidirectional switch 1A and the relay ReD of the bidirectional switch 1D have a short-circuit fault, the command unit 2301 outputs an opening command signal to the relay ReA of the bidirectional switch 1A and the relay ReD of the bidirectional switch 1D and outputs a closing command signal to the relay ReB of the bidirectional switch 1B. In this case, the command unit 2301 outputs an OFF command signal to the switching elements Q1A, Q2A, Q1D, and Q2D and outputs an ON command signal to the switching elements Q1B and Q2B. The determination unit 2304 determines that the relays ReA and ReD are normal in a case where a state where an absolute value of a difference voltage indicated by difference voltage information received from the difference calculation unit 303 is larger than a difference voltage threshold value continues for a preset determination period in a state where the command unit 2301 outputs an opening command signal to the relay ReA of the bidirectional switch 1A and the relay ReD of the bidirectional switch 1D and outputs a closing command signal to the relays ReB. On the other hand, the determination unit 2304 determines that at least one of the relays ReA and ReD have a short-circuit fault in a case where a state where the absolute value of the difference voltage is equal to or smaller than the difference voltage threshold value continues for the determination period in a state where the command unit 2301 outputs an opening command signal to the relays ReA and ReD and outputs a closing command signal to the relays ReB. In a case where the determination unit 2304 determines whether or not the relay ReB of the bidirectional switch 1B and the relay ReD of the bidirectional switch 1D have a short-circuit fault, the command unit 2301 outputs an opening command signal to the relays ReB and ReD outputs a closing command signal to the relays ReA.

In a case where the determination unit 2304 determines whether or not the relay ReA of the bidirectional switch 1A has a short-circuit fault, the command unit 2301 outputs an opening command signal to the relay ReA of the bidirectional switch 1A and outputs a closing command signal to the relays ReB and ReD. In this case, the command unit 2301 outputs an OFF command signal to the switching elements Q1A and Q2A and outputs an ON command signal to the switching elements Q1B, Q2B, Q1D, and Q2D. The determination unit 2304 determines that the relay ReA is normal in a case where a state where an absolute value of a difference voltage between a voltage amplitude measured by the voltmeter 12A and a voltage amplitude measured by the voltmeter 13A is larger than a difference voltage threshold value continues for the determination period in a state where the command unit 2301 outputs an opening command signal to the relay ReA of the bidirectional switch 1A and outputs a closing command signal to the relays ReB and ReD. On the other hand, the determination unit 2304 determines that the relay ReA has a short-circuit fault in a case where the absolute value of the difference voltage is equal to or smaller than the preset difference voltage threshold value in a state where the command unit 2301 outputs an opening command signal to the relay ReA of the bidirectional switch 1A and outputs a closing command signal to the relays ReB, and ReD.

Furthermore, in a case where the determination unit 2304 determines whether or not the switching elements Q1A, Q2A, Q1B, and Q2B have an open fault, the command unit 2301 outputs an opening command signal to the relays ReA and ReB and outputs a closing command signal to the relay ReD. In this case, the command unit 2301 outputs an ON command signal to all of the switching elements Q1A, Q2A, Q1B, and Q2B. In a case where the switching elements Q1A, Q2A, Q1B, and Q2B include a switching element for which an absolute value of a difference voltage indicated by difference voltage information received from the difference calculation unit 303 is larger than the difference voltage threshold value while the relays ReA and ReB are in an opened state and the relay ReD is in a closed state, the determination unit 2304 determines that the switching element has an open fault.

In a case where the determination unit 2304 determines whether or not the relays ReA and ReB have an open fault, the command unit 2301 outputs an OFF command signal to Q1A, Q2A, Q1B, and Q2B and outputs a closing command signal to the relay ReD. This shifts the switching elements Q1A, Q2A, Q1B, and Q2B into an OFF state and shifts the relay ReD into a closed state. In this case, the command unit 2301 outputs a closing command signal to all of the relays ReA and ReB. In a case where the relays ReA and ReB include a relay for which an absolute value of a difference voltage indicated by difference voltage information received from the difference calculation unit 303 is larger than the difference voltage threshold value while the switching elements Q1A, Q2A, Q1B, and Q2B are in an OFF state and the relay ReD is in a closed state, the determination unit 2304 determines that the relay has an open fault.

Furthermore, in a case where the determination unit 2304 determines whether or not the switching elements Q1D and Q2D have an open fault, the command unit 2301 outputs an opening command signal to the relays ReA and ReD and outputs an OFF command signal to Q1A and Q2A. Furthermore, the command unit 2301 outputs an ON command signal to Q1D and Q2D. The switching elements Q1A, Q2A, Q1B, and Q2B are in an ON state, and the relay ReB is in a closed state. The determination unit 2304 determines that the switching elements Q1D and Q1D have an open fault in a case where an absolute value of a difference voltage indicated by difference voltage information received from the difference calculation unit 303 is larger than the difference voltage threshold value in this state.

In a case where the determination unit 2304 determines whether or not the relay ReD has an open fault, the command unit 2301 outputs an opening command signal to the relay ReA and outputs an OFF command signal to Q1A, Q2A, Q1D, and Q2D. Furthermore, the command unit 2301 outputs a closing command signal to the relay ReD. The switching elements Q1B and Q2B are in an ON state, and the relay ReB is in a closed state. The determination unit 2304 determines that the relay ReD has an open fault in a case where an absolute value of a difference voltage indicated by difference voltage information received from the difference calculation unit 303 is larger than the difference voltage threshold value in this state. The determination unit 2304 causes information indicative of a determination result to be stored in the determination result storage 332.

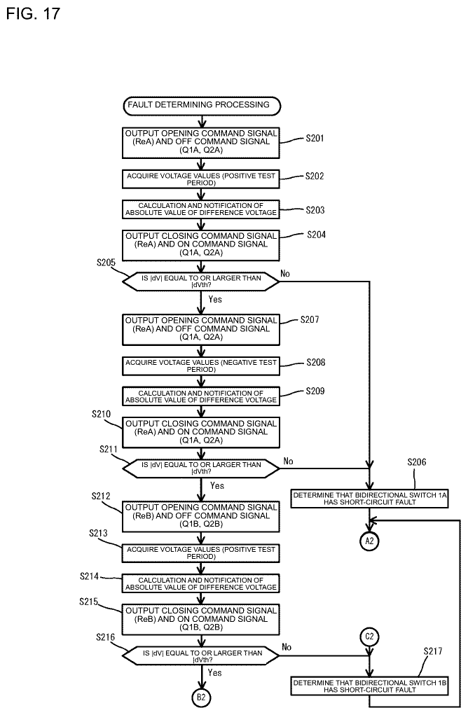

Next, the fault determining processing performed by the determination unit 2304 according to the present preferred embodiment is described with reference to FIGS. 17 to 20. Note that it is assumed that all of the relays ReA, ReB, and ReD of the bidirectional switches 1A, 1B, and 1D are in a closed state and all of the switching elements Q1A, Q2A, Q1B, Q2B, Q1D, and Q2D are in an ON state at the start of the fault determining processing. As illustrated in FIG. 17, first, the command unit 2301 outputs an opening command signal to the relay ReA and outputs an OFF command signal to the switching elements Q1A and Q2A by referring to test case information corresponding to the identification information IDT[10] stored in the test case storage 2331 upon notification of test period start notification information of a test period of a positive polarity from the voltage acquisition unit 302 (step S201). The command unit 2301 maintains the relays ReB and ReD in a closed state and maintains the switching elements Q1B, Q2B, Q1D, and Q2D in an ON state. Next, the voltage acquisition unit 302 acquires a voltage value measured by the voltmeter 12A and a voltage value measured by the voltmeter 13A during the test period of the positive polarity (step S202). Subsequently, the difference calculation unit 303 calculates an absolute value of a difference voltage between the voltage value measured by the voltmeter 12A and the voltage value measured by the voltmeter 13A and notifies the determination unit 2304 of the calculated absolute value of the difference voltage (step S203). Then, the command unit 2301 outputs a closing command signal to the relay ReA and outputs an ON command signal to the switching elements Q1A and Q2A upon notification of test period end notification information from the voltage acquisition unit 302 (step S204). Next, the determination unit 2304 determines whether or not the absolute value |dV| of the difference voltage indicated by the difference voltage information received from the difference calculation unit 303 is equal to or larger than a difference voltage threshold value |dVth| (step S205). In a case where the determination unit 2304 determines that the absolute value |dV| of the difference voltage is smaller than the difference voltage threshold value |dVth| (step S205: No), the determination unit 2304 determines that the bidirectional switch 1A has a short-circuit fault (step S206), and the fault determining processing is finished.

On the other hand, assume that the determination unit 2304 determines that the absolute value |dV| of the difference voltage is equal to or larger than the difference voltage threshold value |dVth| (step S205: Yes). In this case, the command unit 2301 outputs an opening command signal to the relay ReA and outputs an OFF command signal to the switching elements Q1A and Q2A again upon notification of test period start notification information of a test period of a negative polarity from the voltage acquisition unit 302 (step S207). The command unit 2301 maintains the relays ReB and ReD in a closed state and maintains the switching elements Q1B, Q2B, Q1D, and Q2D in an ON state. Subsequently, the voltage acquisition unit 302 acquires a voltage value measured by the voltmeter 12A and a voltage value measured by the voltmeter 13A during the test period of the negative polarity (step S208). Then, the difference calculation unit 303 calculates an absolute value of a difference voltage between the voltage value measured by the voltmeter 12A and the voltage value measured by the voltmeter 13A and notifies the determination unit 2304 of the calculated absolute value of the difference voltage (step S209). Next, the command unit 2301 outputs a closing command signal to the relay ReA and outputs an ON command signal to the switching elements Q1A and Q2A upon notification of test period end notification information from the voltage acquisition unit 302 (step S210). Subsequently, the determination unit 2304 determines whether or not the absolute value |dV| of the difference voltage indicated by the difference voltage information received from the difference calculation unit 303 is equal to or larger than the difference voltage threshold value |dVth| (step S211). In a case where the determination unit 2304 determines that the absolute value |dV| of the difference voltage is smaller than the difference voltage threshold value |dVth| (step S211: No), the determination unit 2304 determines that the bidirectional switch 1A has a short-circuit fault (step S206), and the fault determining processing is finished.

On the other hand, assume that the determination unit 2304 determines that the absolute value |dV| of the difference voltage is equal to or larger than the difference voltage threshold value |dVth| (step S211: Yes). In this case, the command unit 2301 outputs an opening command signal to the relay ReB and outputs an OFF command signal to the switching elements Q1B and Q2B by referring to test case information corresponding to the identification information IDT stored in the test case storage 331 upon notification of test period start notification information of a test period of a positive polarity from the voltage acquisition unit 302 (step S212). The command unit 2301 maintains the relays ReA and ReD in a closed state and maintains the switching elements Q1A, Q2A, Q1D, and Q2D in an ON state. Then, the voltage acquisition unit 302 acquires a voltage value measured by the voltmeter 12B and a voltage value measured by the voltmeter 13B during the test period of the positive polarity (step S213). Next, the difference calculation unit 303 calculates an absolute value of a difference voltage between the voltage value measured by the voltmeter 12B and the voltage value measured by the voltmeter 13B and notifies the determination unit 2304 of the calculated absolute value of the difference voltage (step S214). Subsequently, the command unit 2301 outputs a closing command signal to the relay ReB and outputs an ON command signal to the switching elements Q1B and Q2B upon notification of test period end notification information from the voltage acquisition unit 302 (step S215). Then, the determination unit 2304 determines whether or not the absolute value |dV| of the difference voltage indicated by the difference voltage information received from the difference calculation unit 303 is equal to or larger than the difference voltage threshold value |dVth| (step S216). In a case where the determination unit 2304 determines that the absolute value |dV| of the difference voltage is smaller than the difference voltage threshold value |dVth| (step S216: No), the determination unit 2304 determines that the bidirectional switch 1B has a short-circuit fault (step S217), and the fault determining processing is finished.

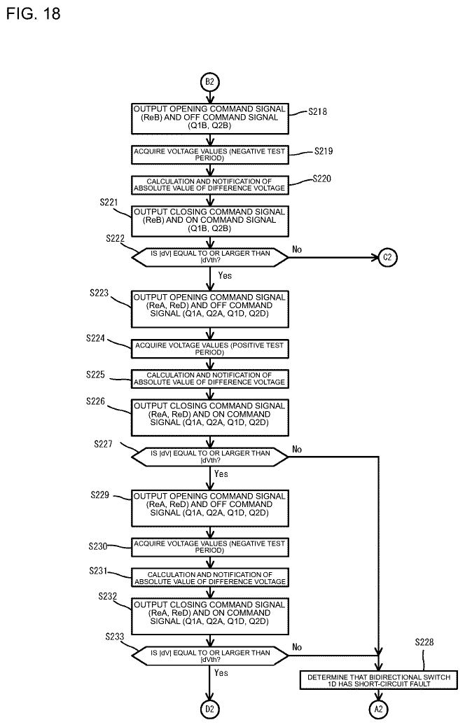

On the other hand, assume that the determination unit 2304 determines that the absolute value |dV| of the difference voltage is equal to or larger than the difference voltage threshold value |dVth| (step S16: Yes). In this case, as illustrated in FIG. 18, the command unit 2301 outputs an opening command signal to the relay ReB and outputs an OFF command signal to the switching elements Q1B and Q2B again upon notification of test period start notification information of a test period of a negative polarity from the voltage acquisition unit 302 (step S218). Next, the voltage acquisition unit 302 acquires a voltage value measured by the voltmeter 12B and a voltage value measured by the voltmeter 13B during the test period of the negative polarity (step S219). Subsequently, the difference calculation unit 303 calculates an absolute value of a difference voltage between the voltage value measured by the voltmeter 12B and the voltage value measured by the voltmeter 13B and notifies the determination unit 2304 of the calculated absolute value of the difference voltage (step S220). Then, the command unit 2301 outputs a closing command signal to the relay ReB and outputs an ON command signal to the switching elements Q1B and Q2B upon notification of test period end notification information from the voltage acquisition unit 302 (step S221). Next, the determination unit 2304 determines whether or not the absolute value |dV| of the difference voltage indicated by the difference voltage information received from the difference calculation unit 303 is equal to or larger than the difference voltage threshold value |dVth| (step S222). In a case where the determination unit 2304 determines that the absolute value |dV| of the difference voltage is smaller than the difference voltage threshold value |dVth| (step S222: No), the determination unit 2304 determines that the bidirectional switch 1B has a short-circuit fault (step S217) as illustrated in FIG. 17, and the fault determining processing is finished.

On the other hand, as illustrated in FIG. 18, assume that the determination unit 2304 determines that the absolute value |dV| of the difference voltage is equal to or larger than the difference voltage threshold value |dVth| (step S222: Yes). In this case, the command unit 2301 outputs an opening command signal to the relays ReA and ReD and outputs an OFF command signal to the switching elements Q1A, Q2A, Q1D, and Q2D by referring to test case information corresponding to the identification information IDT stored in the test case storage 2331 upon notification of test period start notification information of a test period of a positive polarity from the voltage acquisition unit 302 (step S223). The command unit 2301 maintains the relay ReB in a closed state and maintains the switching elements Q1B and Q2B in an ON state. Then, the voltage acquisition unit 302 acquires a voltage value measured by the voltmeter 12B and a voltage value measured by the voltmeter 13B during the test period of the positive polarity (step S224). Subsequently, the difference calculation unit 303 calculates an absolute value of a difference voltage between the voltage value measured by the voltmeter 12B and the voltage value measured by the voltmeter 13B and notifies the determination unit 2304 of the calculated absolute value of the difference voltage (step S225). Then, the command unit 2301 outputs a closing command signal to the relays ReA and ReD and outputs an ON command signal to the switching elements Q1A, Q2A, Q1D, and Q2D upon notification of test period end notification information from the voltage acquisition unit 302 (step S226). Next, the determination unit 2304 determines whether or not the absolute value |dV| of the difference voltage indicated by the difference voltage information received from the difference calculation unit 303 is equal to or larger than the difference voltage threshold value |dVth| (step S227). In a case where the determination unit 2304 determines that the absolute value |dV| of the difference voltage is smaller than the difference voltage threshold value |dVth| (step S227: No), the determination unit 2304 determines that the bidirectional switch 1D has a short-circuit fault (step S228), and the fault determining processing is finished.

On the other hand, assume that the determination unit 2304 determines that the absolute value |dV| of the difference voltage is equal to or larger than the difference voltage threshold value |dVth| (step S227: Yes). In this case, the command unit 2301 outputs an opening command signal to the relays ReA and ReD and outputs an OFF command signal to the switching elements Q1A, Q2A, Q1D, and Q2D again upon notification of test period start notification information of a test period of a negative polarity from the voltage acquisition unit 302 (step S229). Subsequently, the voltage acquisition unit 302 acquires a voltage value measured by the voltmeter 12B and a voltage value measured by the voltmeter 13B during the test period of the negative polarity (step S230). Then, the difference calculation unit 303 calculates an absolute value of a difference voltage between the voltage value measured by the voltmeter 12B and the voltage value measured by the voltmeter 13B and notifies the determination unit 2304 of the calculated absolute value of the difference voltage (step S231). Next, the command unit 2301 outputs a closing command signal to the relays ReA and ReD and outputs an ON command signal to the switching elements Q1A, Q2A, Q1D, and Q2D upon notification of test period end notification information from the voltage acquisition unit 302 (step S232). Subsequently, the determination unit 2304 determines whether or not the absolute value |dV| of the difference voltage indicated by the difference voltage information received from the difference calculation unit 303 is equal to or larger than the difference voltage threshold value |dVth| (step S233). In a case where the determination unit 2304 determines that the absolute value |dV| of the difference voltage is smaller than the difference voltage threshold value |dVth| (step S233: No), the determination unit 2304 determines that the bidirectional switch 1D has a short-circuit fault (step S228), and the fault determining processing is finished.

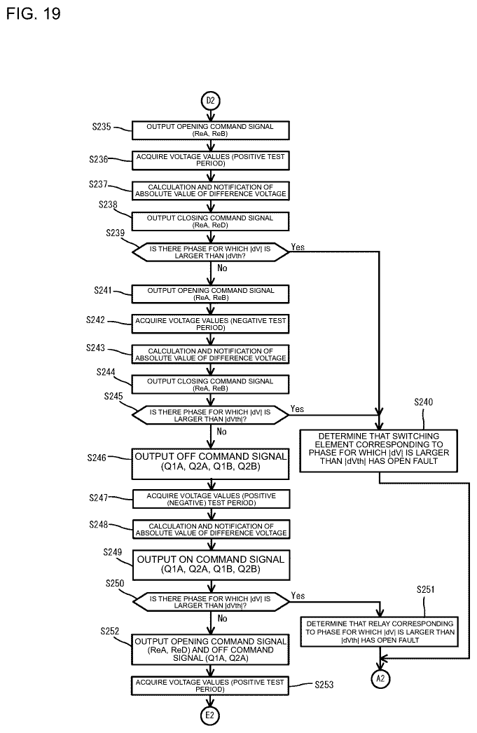

On the other hand, assume that the determination unit 2304 determines that the absolute value |dV| of the difference voltage is equal to or larger than the difference voltage threshold value |dVth| (step S233: Yes). In this case, as illustrated in FIG. 19, the command unit 2301 outputs an opening command signal to the relays ReA and ReB by referring to test case information corresponding to the identification information IDT stored in the test case storage 2331 upon notification of test period start notification information of a test period of a positive polarity from the voltage acquisition unit 302 (step S235). The command unit 2301 maintains the relay ReD in a closed state and maintains the switching elements Q1A, Q2A, Q1B, Q2B, Q1D, and Q2D in an ON state. Then, the voltage acquisition unit 302 acquires voltage values measured by the voltmeters 12A and 12B and voltage values measured by the voltmeters 13A and 13B during the test period of the positive polarity (step S236). Next, the difference calculation unit 303 calculates absolute values of difference voltages between the voltage values measured by the voltmeters 12A and 12B and the voltage values measured by the voltmeters 13A and 13B and notifies the determination unit 2304 of the calculated absolute values of the difference voltages (step S237). Next, the command unit 2301 outputs a closing command signal to the relays ReA and ReB upon notification of test period end notification information from the voltage acquisition unit 302 (step S238). Then, the determination unit 2304 determines whether or not there is a phase for which the absolute value |dV| of the difference voltage indicated by the difference voltage information received from the difference calculation unit 303 is larger than the difference voltage threshold value |dVth| (step S239). Assume that the determination unit 2304 determines that there is a phase for which the absolute value |dV| of the difference voltage is larger than the difference voltage threshold value |dVth| (step S239: Yes). In this case, the determination unit 2304 determines that the switching elements Q1A and Q2A (Q1B and Q2B) of the bidirectional switch 1A (1B) corresponding to the phase for which the absolute value |dV| of the difference voltage is larger than the difference voltage threshold value |dVth| have an open fault (step S240), and the fault determining processing is finished.

On the other hand, assume that the determination unit 2304 determines that the absolute value |dV| of the difference voltage is equal to or smaller than the difference voltage threshold value |dVth| for all phases (step S239: No). In this case, the command unit 2301 outputs an opening command signal to the relays ReA and ReB again upon notification of test period start notification information of a test period of a negative polarity from the voltage acquisition unit 302 (step S241). The command unit 2301 outputs an ON command signal to the switching elements Q1A, Q2A, Q1B, and Q2B. The command unit 2301 maintains the relay ReD in a closed state. Next, the voltage acquisition unit 302 acquires voltage values measured by the voltmeters 12A and 12B and voltage values measured by the voltmeters 13A and 13B during the test period of the negative polarity (step S242). Subsequently, the difference calculation unit 303 calculates absolute values of difference voltages between the voltage values measured by the voltmeters 12A and 12B and the voltage values measured by the voltmeters 13A and 13B and notifies the determination unit 2304 of the calculated absolute values of the difference voltages (step S243). Then, the command unit 2301 outputs a closing command signal to the relays ReA and ReB upon notification of test period end notification information from the voltage acquisition unit 302 (step S244). Next, the determination unit 2304 determines whether or not there is a phase for which the absolute value |dV| of the difference voltage indicated by the difference voltage information received from difference calculation unit 303 is larger than the difference voltage threshold value |dVth| (step S245). Assume that the determination unit 2304 determines that there is a phase for which the absolute value |dV| of the difference voltage is larger than the difference voltage threshold value |dVth| (step S245: Yes). In this case, the determination unit 2304 determines that the switching elements Q1A and Q2A (Q1B and Q2B) of the bidirectional switch 1A (1B) corresponding to the phase for which the absolute value |dV| of the difference voltage is larger than the difference voltage threshold value |dVth| have an open fault (step S240), and the fault determining processing is finished.

On the other hand, assume that the determination unit 2304 determines that the absolute value |dV| of the difference voltage is equal to or smaller than the difference voltage threshold value |dVth| for all phases (step S245: No). In this case, the command unit 2301 outputs an OFF command signal to the switching elements Q1A, Q2A, Q1B, and Q2B by referring to test case information corresponding to the identification information IDT[14] stored in the test case storage 2331 upon notification of test period start notification information of a test period of a positive polarity or a test period of a negative polarity from the voltage acquisition unit 302 (step S246). The command unit 2301 outputs a closing command signal to the relays ReA and ReB. The command unit 2301 maintains the relay ReD in a closed state and maintains the switching elements Q1D and Q2D in an ON state. Then, the voltage acquisition unit 302 acquires voltage values measured by the voltmeters 12A and 12B and voltage values measured by the voltmeters 13A and 13B during the test period of the positive polarity or the test period of the negative polarity (step S247). Subsequently, the difference calculation unit 303 calculates absolute values of difference voltages between the voltage values measured by the voltmeters 12A and 12B and the voltage values measured by the voltmeters 13A and 13B and notifies the determination unit 2304 of the calculated absolute values of the difference voltages (step S248). Then, the command unit 2301 outputs an ON command signal to the switching elements Q1A, Q2A, Q1B, and Q2B upon notification of test period end notification information from the voltage acquisition unit 302 (step S249). Then, the determination unit 2304 determines whether or not there is a phase for which the absolute value |dV| of the difference voltage indicated by the difference voltage information received from the difference calculation unit 303 is larger than the difference voltage threshold value |dVth| (step S250). Assume that the determination unit 2304 determines that there is a phase for which the absolute value |dV| of the difference voltage is larger than the difference voltage threshold value |dVth| (step S250: Yes). In this case, the determination unit 2304 determines that the relay ReA (ReB) of the bidirectional switch 1A (1B) corresponding to the phase for which the absolute value |dV| of the difference voltage is larger than the difference voltage threshold value |dVth| has an open fault (step S251), and the fault determining processing is finished.

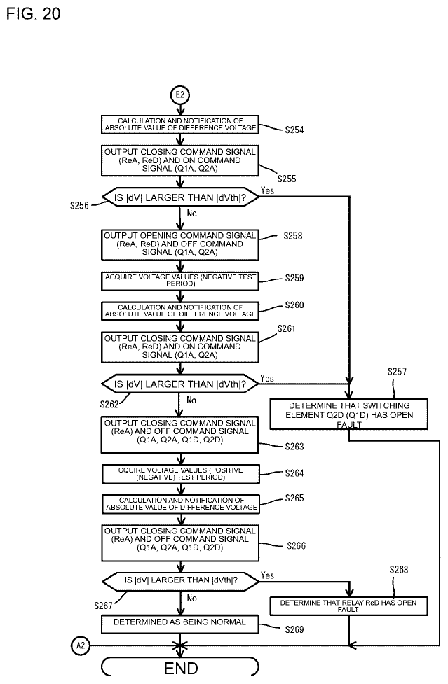

On the other hand, assume that the determination unit 2304 determines that the absolute value |dV| of the difference voltage is equal to or smaller than the difference voltage threshold value |dVth| for all phases (step S250: No). In this case, the command unit 2301 outputs an opening command signal to the relays ReA and ReD and outputs an OFF command signal to the switching elements Q1A and Q2A by referring to test case information corresponding to the identification information IDT[15] stored in the test case storage 2331 upon notification of test period start notification information of a test period of a positive polarity from the voltage acquisition unit 302 (step S252). The command unit 2301 outputs an ON command signal to the switching elements Q1D and Q2D. The command unit 2301 maintains the relay ReB in a closed state and maintains the switching elements Q1B and Q2B in an ON state. Next, the voltage acquisition unit 302 acquires a voltage value measured by the voltmeter 12B and a voltage value measured by the voltmeter 13B during the test period of the positive polarity (step S253). Next, as illustrated in FIG. 20, the difference calculation unit 303 calculates an absolute value of a difference voltage between the voltage value measured by the voltmeter 12B and the voltage value measured by the voltmeter 13B and notifies the determination unit 2304 of the calculated absolute value of the difference voltage (step S254). Then, the command unit 2301 outputs a closing command signal to the relays ReA and ReD and outputs an ON command signal to the switching elements Q1A and Q2A upon notification of test period end notification information from the voltage acquisition unit 302 (step S255). Next, the determination unit 2304 determines whether or not the absolute value |dV| of the difference voltage indicated by the difference voltage information received from the difference calculation unit 303 is larger than the difference voltage threshold value |dVth| (step S256). In a case where the determination unit 2304 determines that the absolute value |dV| of the difference voltage is larger than the difference voltage threshold value |dVth| (step S256: Yes), the determination unit 2304 determines that the switching element Q2D has an open fault (step S257), and the fault determining processing is finished.

On the other hand, assume that the determination unit 2304 determines that the absolute value |dV| of the difference voltage is equal to or smaller than the difference voltage threshold value |dVth| (step S256: No). In this case, the command unit 2301 outputs an opening command signal to the relays ReA and ReD and outputs an OFF command signal to the switching elements Q1A and Q2A again upon notification of test period start notification information of a test period of a negative polarity from the voltage acquisition unit 302 (step S258). The command unit 2301 outputs an ON command signal to the switching elements Q1D and Q2D. The command unit 2301 maintains the relay ReB in a closed state and maintains the switching elements Q1B and Q2B in an ON state. Subsequently, the voltage acquisition unit 302 acquires a voltage value measured by the voltmeter 12B and a voltage value measured by the voltmeter 13B during the test period of the negative polarity (step S259). Then, the difference calculation unit 303 calculates an absolute value of a difference voltage between the voltage value measured by the voltmeter 12B and the voltage value measured by the voltmeter 13B and notifies the determination unit 2304 of the calculated absolute value of the difference voltage (step S260). Next, the command unit 2301 outputs a closing command signal to the relays ReA and ReD and outputs an ON command signal to the switching elements Q1A and Q2A upon notification of test period end notification information from the voltage acquisition unit 302 (step S261). Subsequently, the determination unit 2304 determines whether or not the absolute value |dV| of the difference voltage indicated by the difference voltage information received from the difference calculation unit 303 is larger than the difference voltage threshold value |dVth| (step S262). In a case where the determination unit 2304 determines that the absolute value |dV| of the difference voltage is larger than the difference voltage threshold value |dVth| (step S262: Yes), the determination unit 2304 determines that the switching element Q1D has an open fault (step S257), and the fault determining processing is finished.

On the other hand, assume that the determination unit 2304 determines that the absolute value |dV| of the difference voltage is equal to or smaller than the difference voltage threshold value |dVth| (step S262: No). In this case, the command unit 2301 outputs an opening command signal to the relay ReA and outputs an OFF command signal to the switching elements Q1A, Q2A, Q1D, and Q2D by referring to test case information corresponding to the identification information IDT stored in the test case storage 2331 upon notification of test period start notification information of a test period of a positive polarity or a test period of a negative polarity from the voltage acquisition unit 302 (step S263). The command unit 2301 outputs a closing command signal to the relay ReD. The command unit 2301 maintains the relay ReB in a closed state and maintains the switching elements Q1B and Q2B in an ON state. Then, the voltage acquisition unit 302 acquires a voltage value measured by the voltmeter 12B and a voltage value measured by the voltmeter 13B during the test period of the positive polarity or the test period of the negative polarity (step S264). Next, the difference calculation unit 303 calculates an absolute value of a difference voltage between the voltage value measured by the voltmeter 12B and the voltage value measured by the voltmeter 13B and notifies the determination unit 2304 of the calculated absolute value of the difference voltage (step S265). Subsequently, the command unit 2301 outputs a closing command signal to the relay ReA and outputs an ON command signal to the switching elements Q1A, Q2A, Q1D, and Q2D upon notification of test period end notification information from the voltage acquisition unit 302 (step S266). Subsequently, the determination unit 2304 determines whether or not the absolute value |dV| of the difference voltage indicated by the difference voltage information received from the difference calculation unit 303 is larger than the difference voltage threshold value |dVth| (step S267). In a case where the determination unit 2304 determines that the absolute value |dV| of the difference voltage is larger than the difference voltage threshold value |dVth| (step S267: Yes), the determination unit 2304 determines that the relay ReD has an open fault (step S268), and the fault determining processing is finished. On the other hand, in a case where the determination unit 2304 determines that the absolute value |dV| of the difference voltage is equal to or smaller than the difference voltage threshold value |dVth| (step S267: No), the determination unit 2304 determines that all of the bidirectional switches 1A, 1B, and 1D have no fault and are normal (step S269), and the fault determining processing is finished.

As described above, according to the switching module 2501 according to the present preferred embodiment, the command unit 2301 outputs an opening command signal to the relays ReA and ReD and outputs a closing command signal to the relays ReB. The determination unit 2304 determines that at least one of the relays ReA and ReD has a short-circuit fault in a case where an absolute value of a difference voltage between a voltage measured by the voltmeter 12B and a voltage measured by the voltmeter 13B is equal to or less than a difference voltage threshold value in this state. Therefore, even in a case where impedances of the power conversion circuits 201, 202, 203, and 204 connected to the output terminals te3A and te3B are equal, it is possible to determine whether or not the relay ReD has a fault, and it is therefore possible to detect the presence or absence of a fault for all of the relays ReA, ReB, and ReD included in the switching module 2501.

### Preferred Embodiment 3

A switching module according to the present preferred embodiment includes three first switches, each of which is connected in series between any one of three first input terminals and any one of three first output terminals, and a second switch connected in series between a second input terminal and a second output terminal, as in the switching module according to Preferred Embodiment 1. The switching module according to the present preferred embodiment is different from the switching module according to Preferred Embodiment 1 in that this switching module includes first ammeters that measure first currents flowing through the three first switches and an ammeter that measures a second current flowing through the second switch.

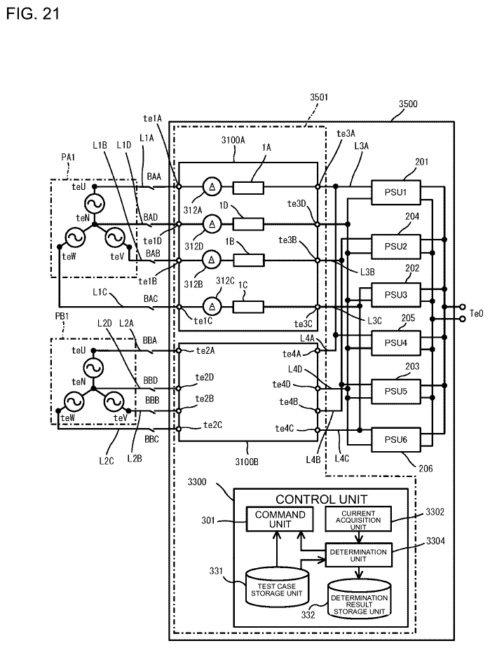

For example, as illustrated in FIG. 21, a power source system 3500 according to the present preferred embodiment receives alternating-current power from an alternating-current power source PA1 or a standby alternating-current power source PB1 and supplies direct-current power to a load such as a server (not illustrated) connected to an output terminal TeO. In FIG. 21, constituent elements similar to those in Preferred Embodiment 1 are given reference signs identical to those in FIG. 1. The power source system 3500 includes six power conversion circuits 201, 202, 203, 204, 205, and 206 and a switching module 3501. The switching module 3501 includes two module bodies 3100A and 3100B and a controller 3300 configured or programmed to control operation of the module bodies 3100A and 3100B.

See FIG. 21 again. The module body 3100A includes four bidirectional switches 1A, 1B, 1C, and 1D and four ammeters 312A, 312B, 312C, and 312D. Note that the module body 3100B has a similar configuration to the module body 3100A, and includes four bidirectional switches (not illustrated) and four ammeters (not illustrated).

The ammeter 312A is connected between an input terminal te1A and the bidirectional switch 1A, and the ammeter 312B is connected between an input terminal te1B and the bidirectional switch 1B. The ammeter 312C is connected between an input terminal te1C and the bidirectional switch 1C, and the ammeter 312D is connected between an input terminal te1D and the bidirectional switch 1D. The ammeter 312A is a first ammeter that measures a current value of a current flowing through the bidirectional switch 1A. The ammeter 312B is a first ammeter that measures a current value of a current flowing through the bidirectional switch 1B. The ammeter 312C is a first ammeter that measures a current value of a current flowing through the bidirectional switch 1C. The ammeter 312D is a second ammeter that measures a current value of a current flowing through the bidirectional switch 1D. Each of the ammeters 312A, 312B, 312C, and 312D continuously outputs a voltage signal reflecting a measured current value to the controller 3300.

The controller 3300 has a similar hardware configuration to the controller 300 according to Preferred Embodiment 1 and is configured or programmed to control operation of the module bodies 3100A and 3100B. The controller 3300 has a command unit 301, a current acquisition unit 3302, and a determination unit 3304. A memory includes a determination result storage 332 and a test case storage 331, as in Preferred Embodiment 1.

The current acquisition unit 3302 samples each of measurement signals input from the ammeters 12A, 12B, 12C, and 12D for a preset sampling period, converts the sampled measurement signal into current value information indicative of a current value, and notifies the determination unit 3304 of the current value information. The current acquisition unit 3302 notifies the command unit 301 and the determination unit 3304 of test period start notification information when a time corresponding to a zero cross point of a phase voltage arrives on the basis of the current value information. In a case where a polarity of a current value indicated by the acquired current value information switches from a negative state to a positive state after passing a zero cross point, the current acquisition unit 3302 notifies the command unit 301 and the determination unit 3304 of test period start notification information indicative of start of a test period of a positive polarity. On the other hand, in a case where a polarity of a current value indicated by the acquired current value information switches from a positive state to a negative state after passing a zero cross point, the current acquisition unit 3302 notifies the command unit 301 and the determination unit 3304 of test period start notification information indicative of start of a test period of a negative polarity. The current acquisition unit 3302 notifies the command unit 301 and the determination unit 3304 of test period end notification information when a preset test period elapses from a time corresponding to a zero cross point of a phase voltage on the basis of the current value information.

The determination unit 3304 determines whether or not the bidirectional switches 1A, 1B, 1C, and 1D have a fault by performing fault determining processing, which will be described later. In a case where the determination unit 3304 determines whether or not a relay ReA of the bidirectional switch 1A and a relay ReD of the bidirectional switch 1D have a short-circuit fault, the command unit 301 outputs an opening command signal to the relay ReA of the bidirectional switch 1A and the relay ReD of the bidirectional switch 1D and outputs a closing command signal to a relay ReB of the bidirectional switch 1B and a relay ReC of the bidirectional switch 1C. In this case, the command unit 301 outputs an OFF command signal to switching elements Q1A, Q2A, Q1D, and Q2D and outputs an ON command signal to switching elements Q1B, Q2B, Q1C, and Q2C. The determination unit 3304 determines that the relays ReA and ReD are normal in a case where a state where an absolute value of a current value indicated by current value information received from the current acquisition unit 3302 is larger than a preset current threshold value, that is, a state where the current value is outside a preset current range continues for a preset determination period in a state where the command unit 301 outputs an opening command signal to the relay ReA of the bidirectional switch 1A and the relay ReD of the bidirectional switch 1D and outputs a closing command signal to the relays ReB and ReC. The current range corresponds to a current value range that uses, as a lower limit, a negative current value whose absolute value is equal to the current threshold value and uses, as an upper limit, a positive current value whose absolute value is equal to the current threshold value. On the other hand, the determination unit 3304 determines that at least one of the relays ReA and ReD has a short-circuit fault in a case where a state where the absolute value of the current value indicated by the current value information is equal to or smaller than the current threshold value, that is, a state where the current value is within the current range continues for the determination period in a state where the command unit 301 outputs an opening command signal to the relays ReA and ReD and outputs a closing command signal to the relays ReB and ReC. Note that in a case where the determination unit 3304 determines whether or not the relay ReB of the bidirectional switch 1B and the relay ReD of the bidirectional switch 1D have a short-circuit fault, the command unit 301 outputs an opening command signal to the relays ReB and ReD and outputs a closing command signal to the relays ReA and ReC. In a case where the determination unit 3304 determines whether or not the bidirectional switches 1C and 1D have a short-circuit fault, the command unit 301 outputs an opening command signal to the relays ReC and ReD and outputs a closing command signal to the relays ReA and ReB.

In a case where the determination unit 3304 determines whether or not the bidirectional switch 1A has a short-circuit fault, the command unit 301 outputs an opening command signal to the relay ReA of the bidirectional switch 1A and outputs a closing command signal to the relays ReB, ReC, and ReD. In this case, the command unit 301 outputs an OFF command signal to the switching elements Q1A and Q2A and outputs an ON command signal to the switching elements Q1B, Q2B, Q1C, Q2C, Q1D, and Q2D. The determination unit 3304 determines that the relay ReA is normal in a case where a state where an absolute value of a current value measured by the ammeter 312A is equal to or smaller than the current threshold value, that is, a state where the current value is within the current range continues for the determination period in a state where the command unit 301 outputs an opening command signal to the relay ReA of the bidirectional switch 1A and outputs a closing command signal to the relays ReB, ReC, and ReD. On the other hand, the determination unit 3304 determines that the relay ReA has a short-circuit fault in a case where a state where the absolute value of the current value measured by the ammeter 312A is larger than the current threshold value, that is, a state where the current value is outside the current range continues for the determination period in a state where the command unit 301 outputs an opening command signal to the relay ReA of the bidirectional switch 1A and outputs a closing command signal to the relays ReB, ReC, and ReD.

Furthermore, in a case where the determination unit 3304 determines whether or not the switching elements Q1A, Q2A, Q1B, Q2B, Q1C, and Q2C have an open fault, the command unit 301 outputs an opening command signal to the relays ReA, ReB, and ReC and outputs a closing command signal to the relay ReD. In this case, the command unit 301 outputs an ON command signal to all of the switching elements Q1A, Q2A, Q1B, Q2B, Q1C, and Q1C. In a case where the switching elements Q1A, Q2A, Q1B, Q2B, Q1C, and Q2C include a switching element for which an absolute value of a current value indicated by current value information received from the current acquisition unit 3302 is smaller than the current threshold value, that is, the current value is within the current range while the relays ReA, ReB, and ReC are in an opened state and the relay ReD is in a closed state, the determination unit 3304 determines that the switching element has an open fault.

In a case where the determination unit 3304 determines whether or not the relays ReA, ReB, and ReC have an open fault, the command unit 301 outputs an OFF command signal to Q1A, Q2A, Q1B, Q2B, Q1C, and Q2C and outputs a closing command signal to the relay ReD. This shifts the switching elements Q1A, Q2A, Q1B, Q2B, Q1C, and Q2C into an OFF state and shifts the relay ReD into a closed state. In this case, the command unit 301 outputs a closing command signal to all of the relays ReA, ReB, and ReC. In a case where the relays ReA, ReB, and ReC include a relay for which an absolute value of a current value indicated by current value information received from the current acquisition unit 3302 is smaller than the current threshold value, that is, the current value is within the current range while the switching elements Q1A, Q2A, Q1B, Q2B, Q1C, and Q2C are in an OFF state and the relay ReD is in a closed state, the determination unit 3304 determines that the relay has an open fault.

Furthermore, in a case where the determination unit 3304 determines whether or not the switching elements Q1D and Q2D have an open fault, the command unit 301 outputs an opening command signal to the relays ReA and ReD and outputs an OFF command signal to Q1A and Q2A. The command unit 301 outputs an ON command signal to Q1D and Q2D. The switching elements Q1A, Q2A, Q1B, Q2B, Q1C, and Q2C are in an ON state, and the relays ReB and ReC are in a closed state. The determination unit 3304 determines that the switching elements Q1D and Q2D have an open fault in a case where an absolute value of a current value indicated by current value information received from the current acquisition unit 3302 is smaller than the current threshold value, that is, the current value is within the current range in this state.

In a case where the determination unit 3304 determines whether or not the relay ReD has an open fault, the command unit 301 outputs an opening command signal to the relay ReA and outputs an OFF command signal to Q1A, Q2A, Q1D, and Q2D. The command unit 301 outputs a closing command signal to the relay ReD. The switching elements Q1B, Q2B, Q1C, and Q2C are in an ON state, and the relays ReB and ReC are in a closed state. The determination unit 3304 determines that the relay ReD has an open fault in a case where an absolute value of a current value indicated by current value information received from the current acquisition unit 3302 is smaller than the current threshold value, that is, the current value is within the current range in this state. The determination unit 3304 causes information indicative of a determination result to be stored in the determination result storage 332.

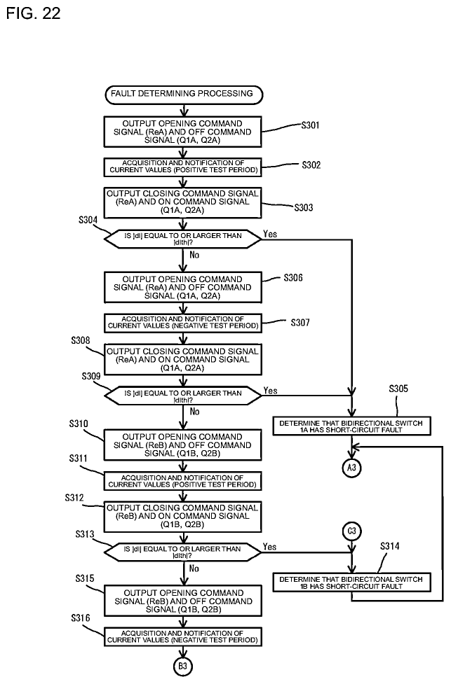

Next, the fault determining processing performed by the determination unit 3304 according to the present preferred embodiment is described with reference to FIGS. 22 to 25. Note that it is assumed that all of the relays ReA, ReB, ReC, and ReD of the bidirectional switches 1A, 1B, 1C, and 1D are in a closed state and all of the switching elements Q1A, Q2A, Q1B, Q2B, Q1C, Q2C, Q1D, and Q2D are in an ON state at the start of the fault determining processing. As illustrated in FIG. 22, first, the command unit 301 outputs an opening command signal to the relay ReA and outputs an OFF command signal to the switching elements Q1A and Q2A by referring to test case information corresponding to the identification information IDT[0] stored in the test case storage 331 upon notification of test period start notification information of a test period of a positive polarity from the current acquisition unit 3302 (step S301). The command unit 301 maintains the relays ReB, ReC, and ReD in a closed state and maintains the switching elements Q1B, Q2B, Q1C, Q2C, Q1D, and Q2D in an ON state. Next, the current acquisition unit 3302 acquires a current value measured by the ammeter 312A during the test period of the positive polarity and notifies the determination unit 3304 of current value information indicative of the acquired current value (step S302). To “acquire a current value” means converting a measurement signal input from the ammeter 312A into current value information. The same applies hereinafter. Subsequently, the command unit 301 outputs a closing command signal to the relay ReA and outputs an ON command signal to the switching elements Q1A and Q2A upon notification of test period end notification information from the current acquisition unit 3302 (step S303). Then, the determination unit 3304 determines whether or not an absolute value |dI| of the current value indicated by the current value information received from the current acquisition unit 3302 is equal to or larger than a preset current threshold value |dIth| (step S304). In a case where the determination unit 3304 determines that the absolute value |dI| of the current value is equal to or larger than the current threshold value |dIth| (step S304: Yes), the determination unit 3304 determines that the bidirectional switch 1A has a short-circuit fault (step S305), and the fault determining processing is finished.

On the other hand, assume that the determination unit 3304 determines that the absolute value |dI| of the current value is smaller than the current threshold value |dIth| (step S304: No). In this case, the command unit 301 outputs an opening command signal to the relay ReA and outputs an OFF command signal to the switching elements Q1A and Q2A again upon notification of test period start notification information of a test period of a negative polarity from the current acquisition unit 3302 (step S306). The command unit 301 maintains the relays ReB, ReC, and ReD in a closed state and maintains the switching elements Q1B, Q2B, Q1C, Q2C, Q1D, and Q2D in an ON state. Next, the current acquisition unit 3302 acquires a current value measured by the ammeter 312A during the test period of the negative polarity and notifies the determination unit 3304 of current value information indicative of the acquired current value (step S307). Subsequently, the command unit 301 outputs a closing command signal to the relay ReA and outputs an ON command signal to the switching elements Q1A and Q2A upon notification of test period end notification information from the current acquisition unit 3302 (step S308). Then, the determination unit 3304 determines whether or not an absolute value |dI| of the current value indicated by the current value information received from the current acquisition unit 3302 is equal to or larger than the current threshold value |dIth| (step S309). In a case where the determination unit 3304 determines that the absolute value |dI| of the current value is equal to or larger than the current threshold value |dIth| (step S309: Yes), the determination unit 3304 determines that the bidirectional switch 1A has a short-circuit fault (step S305), and the fault determining processing is finished.

On the other hand, assume that the determination unit 3304 determines that the absolute value |dI| of the current value is smaller than the current threshold value |dIth| (step S309: No). In this case, the command unit 301 outputs an opening command signal to the relay ReB and outputs an OFF command signal to the switching elements Q1B and Q2B by referring to test case information corresponding to the identification information IDT[1] stored in the test case storage 331 upon notification of test period start notification information of a test period of a positive polarity from the current acquisition unit 3302 (step S310). The command unit 301 maintains the relays ReA, ReC, and ReD in a closed state and maintains the switching elements Q1A, Q2A, Q1C, Q2C, Q1D, and Q2D in an ON state. Next, the current acquisition unit 3302 acquires a current value measured by the ammeter 312B during the test period of the positive polarity and notifies the determination unit 3304 of current value information indicative of the acquired current value (step S311). Subsequently, the command unit 301 outputs a closing command signal to the relay ReB and outputs an ON command signal to the switching elements Q1B and Q2B upon notification of test period end notification information from the current acquisition unit 3302 (step S312). Then, the determination unit 3304 determines whether or not an absolute value |dI| of the current value indicated by the current value information received from the current acquisition unit 3302 is equal to or larger than the current threshold value |dIth| (step S313). In a case where the determination unit 3304 determines that the absolute value |dI| of the current value is equal to or larger than the current threshold value |dIth| (step S313: Yes), the determination unit 3304 determines that the bidirectional switch 1B has a short-circuit fault (step S314), and the fault determining processing is finished.

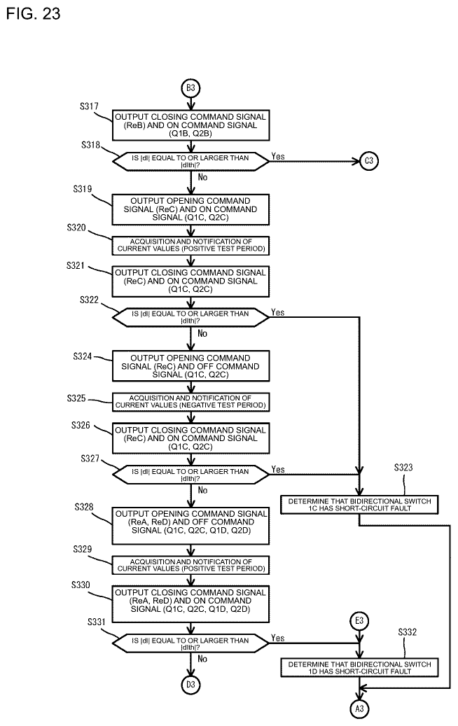

On the other hand, assume that the determination unit 3304 determines that the absolute value |dI| of the current value is smaller than the current threshold value |dIth| (step S313: No). In this case, the command unit 301 outputs an opening command signal to the relay ReB and outputs an OFF command signal to the switching elements Q1B and Q2B again upon notification of test period start notification information of a test period of a negative polarity from the current acquisition unit 3302 (step S315). Next, the current acquisition unit 3302 acquires a current value measured by the ammeter 312B during the test period of the negative polarity and notifies the determination unit 3304 of current value information indicative of the acquired current value (step S316). Subsequently, as illustrated in FIG. 23, the command unit 301 outputs a closing command signal to the relay ReB and outputs an ON command signal to the switching elements Q1B and Q2B upon notification of test period end notification information from the current acquisition unit 3302 (step S317). Then, the determination unit 3304 determines whether or not an absolute value |dI| of the current value indicated by the current value information received from the current acquisition unit 3302 is equal to or larger than the current threshold value |dIth| (step S318). In a case where the determination unit 3304 determines that the absolute value |dI| of the current value is equal to or larger than the current threshold value |dIth| (step S318: Yes), the determination unit 3304 determines that the bidirectional switch 1B has a short-circuit fault (step S314) as illustrated in FIG. 22, and the fault determining processing is finished.

On the other hand, as illustrated in FIG. 23, assume that the determination unit 3304 determines that the absolute value |dI| of the current value is smaller than the current threshold value |dIth| (step S318: No). In this case, the command unit 301 outputs an opening command signal to the relay ReC and outputs an OFF command signal to the switching elements Q1C and Q2C by referring to test case information corresponding to the identification information IDT[2] stored in the test case storage 331 upon notification of test period start notification information of a test period of a negative polarity from the current acquisition unit 3302 (step S319). The command unit 301 maintains the relays ReA, ReB, and ReD in a closed state and maintains the switching elements Q1A, Q2A, Q1B, Q2B, Q1D, and Q2D in an ON state. Next, the current acquisition unit 3302 acquires a current value measured by the ammeter 312C during the test period of the positive polarity and notifies the determination unit 3304 of current value information indicative of the acquired current value (step S320). Subsequently, the command unit 301 outputs a closing command signal to the relay ReC and outputs an ON command signal to the switching elements Q1C and Q2C upon notification of test period end notification information from the current acquisition unit 3302 (step S321). Then, the determination unit 3304 determines whether or not an absolute value |dI| of the current value indicated by the current value information received from the current acquisition unit 3302 is equal to or larger than the current threshold value |dIth| (step S322). In a case where the determination unit 3304 determines that the absolute value |dI| of the current value is equal to or larger than the current threshold value |dIth| (step S322: Yes), the determination unit 3304 determines that the bidirectional switch 1C has a short-circuit fault (step S323), and the fault determining processing is finished.

On the other hand, assume that the determination unit 3304 determines that the absolute value |dI| of the current value is smaller than the current threshold value |dIth| (step S322: No). In this case, the command unit 301 outputs an opening command signal to the relay ReC and outputs an OFF command signal to the switching elements Q1C and Q2C again upon notification of test period start notification information of a test period of a negative polarity from the current acquisition unit 3302 (step S324). Next, the current acquisition unit 3302 acquires a current value measured by the ammeter 312C during the test period of the negative polarity and notifies the determination unit 3304 of current value information indicative of the acquired current value (step S325). Subsequently, the command unit 301 outputs a closing command signal to the relay ReC and outputs an ON command signal to the switching elements Q1C and Q2C upon notification of test period end notification information from the current acquisition unit 3302 (step S326). Then, the determination unit 3304 determines whether or not an absolute value |dI| of the current value indicated by the current value information received from the current acquisition unit 3302 is equal to or larger than the current threshold value |dIth| (step S327). In a case where the determination unit 3304 determines that the absolute value |dI| of the current value is equal to or larger than the current threshold value (step S327: Yes), the determination unit 3304 determines that the bidirectional switch 1C has a short-circuit fault (step S323), and the fault determining processing is finished.

On the other hand, assume that the determination unit 3304 determines that the absolute value |dI| of the current value is smaller than the current threshold value |dIth| (step S327: No). In this case, the command unit 301 outputs an opening command signal to the relays ReA and ReD and outputs an OFF command signal to the switching elements Q1A, Q2A, Q1D, and Q2D by referring to test case information corresponding to the identification information IDT[3] stored in the test case storage 331 upon notification of test period start notification information of a test period of a positive polarity from the current acquisition unit 3302 (step S328). The command unit 301 maintains the relays ReB and ReC in a closed state and maintains the switching elements Q1B, Q2B, Q1C, and Q2C in an ON state. Then, the current acquisition unit 3302 acquires a current value measured by the ammeter 312B during the test period of the positive polarity and notifies the determination unit 3304 of current value information indicative of the acquired current value (step S329). Next, the command unit 301 outputs a closing command signal to the relays ReA and ReD and outputs an ON command signal to the switching elements Q1A, Q2A, Q1D, and Q2D upon notification of test period end notification information from the current acquisition unit 3302 (step S330). Subsequently, the determination unit 3304 determines whether or not an absolute value |dI| of the current value indicated by the current value information received from the current acquisition unit 3302 is equal to or larger than the current threshold value |dIth| (step S331). In a case where the determination unit 3304 determines that the absolute value |dI| of the current value is equal to or larger than the current threshold value |dIth| (step S331: Yes), the determination unit 3304 determines that the bidirectional switch 1D has a short-circuit fault (step S332), and the fault determining processing is finished.

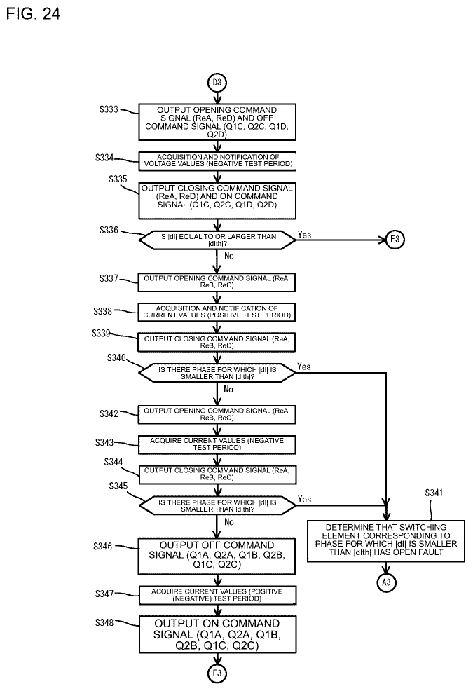

On the other hand, assume that the determination unit 3304 determines that the absolute value |dI| of the current value is smaller than the current threshold value |dIth| (step S331: No). In this case, as illustrated in FIG. 24, the command unit 301 outputs an opening command signal to the relays ReA and ReD and outputs an OFF command signal to the switching elements Q1A, Q2A, Q1D, and Q2D again upon notification of test period start notification information of a test period of a negative polarity from the current acquisition unit 3302 (step S333). Then, the current acquisition unit 3302 acquires a current value measured by the ammeter 312B during the test period of the negative polarity and notifies the determination unit 3304 of current value information indicative of the acquired current value (step S334). Next, the command unit 301 outputs a closing command signal to the relays ReA and ReD and outputs an ON command signal to the switching elements Q1A, Q2A, Q1D, and Q2D upon notification of test period end notification information from the current acquisition unit 3302 (step S335). Subsequently, the determination unit 3304 determines whether or not an absolute value IdIl of the current value indicated by the current value information received from the current acquisition unit 3302 is equal to or larger than the current threshold value |dIth| (step S336). In a case where the determination unit 3304 determines that the absolute value |dI| of the current value is equal to or larger than the current threshold value |dIth| (step S336: Yes), the determination unit 3304 determines that the bidirectional switch 1D has a short-circuit fault (step S332) as illustrated in FIG. 23, and the fault determining processing is finished.

On the other hand, as illustrated in FIG. 24, assume that the determination unit 3304 determines that the absolute value |dI| of the current value is smaller than the current threshold value |dIth| (step S336: Yes). In this case, the command unit 301 outputs an opening command signal to the relays ReA, ReB, and ReC by referring to test case information corresponding to the identification information IDT[4] stored in the test case storage 331 upon notification of test period start notification information of a test period of a positive polarity from the current acquisition unit 3302 (step S337). The command unit 301 maintains the relay ReD in a closed state and maintains the switching elements Q1A, Q2A, Q1B, Q2B, Q1C, Q2C, Q1D, and Q2D in an ON state. Then, the current acquisition unit 3302 acquires current values measured by the ammeters 312A, 312B, and 312C during the test period of the positive polarity and notifies the determination unit 3304 of current value information indicative of the acquired current value (step S338). Next, the command unit 301 outputs a closing command signal to the relays ReA, ReB, and ReC upon notification of test period end notification information from the current acquisition unit 3302 (step S339). Subsequently, the determination unit 3304 determines whether or not there is a phase for which an absolute value |dI| of the current value indicated by the current value information received from the current acquisition unit 3302 is smaller than the current threshold value |dIth| (step S340). Assume that the determination unit 3304 determines that there is a phase for which the absolute value |dI| of the current value is smaller than the current threshold value |dIth| (step S340: Yes). In this case, the determination unit 3304 determines that the switching element Q2A (Q2B, Q2C) of the bidirectional switch 1A (1B, 1C) corresponding to the phase for which the absolute value |dI| of the current value is smaller than the current threshold value |dIth| has an open fault (step S341), and the fault determining processing is finished.

On the other hand, assume that the determination unit 3304 determines that the absolute value |dI| of the current value is equal to or larger than the current threshold value |dIth| for all phases (step S340: No). In this case, the command unit 301 outputs an opening command signal to the relays ReA, ReB, and ReC again upon notification of test period start notification information of a test period of a negative polarity from the current acquisition unit 3302 (step S342). The command unit 301 outputs an ON command signal to the switching elements Q1A, Q2A, Q1B, Q2B, Q1C, and Q2C. The command unit 301 maintains the relay ReD in a closed state and maintains the switching elements Q1A, Q2A, Q1B, Q2B, Q1C, Q2C, Q1D, and Q2D in an ON state. Then, the current acquisition unit 3302 acquires current values measured by the ammeters 312A, 312B, and 312C during the test period of the negative polarity and notifies the determination unit 3304 of current value information indicative of the acquired current value (step S343). Next, the command unit 301 outputs a closing command signal to the relays ReA, ReB, and ReC upon notification of test period end notification information from the current acquisition unit 3302 (step S344). Subsequently, the determination unit 3304 determines whether or not there is a phase for which an absolute value |dI| of the current value indicated by the current value information received from the current acquisition unit 3302 is smaller than the current threshold value |dIth| (step S345). Assume that the determination unit 3304 determines that there is a phase for which the absolute value |dI| of the current value is smaller than the current threshold value |dIth| (step S345: Yes). In this case, the determination unit 3304 determines that the switching element Q1A (Q1B, Q1C) of the bidirectional switch 1A (1B, 1C) corresponding to the phase for which the absolute value |dI| of the current value is smaller than the current threshold value |dIth| has an open fault (step S341), and the fault determining processing is finished.

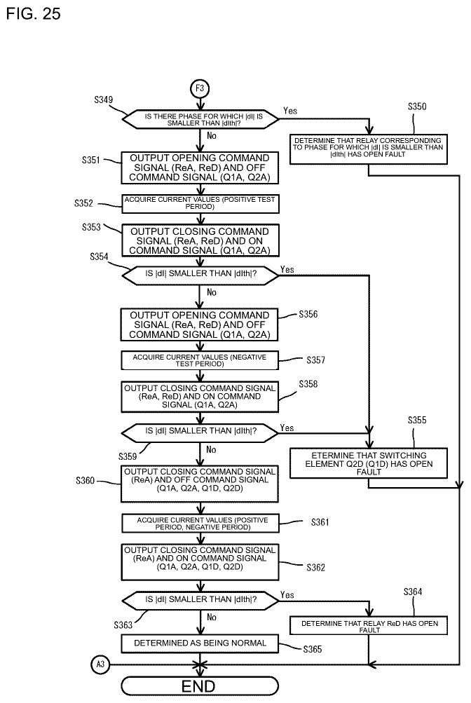

On the other hand, assume that the determination unit 3304 determines that the absolute value |dI| of the current value is equal to or larger than the current threshold value |dIth| for all phases (step S345: No). In this case, the command unit 301 outputs an OFF command signal to the switching elements Q1A, Q2A, Q1B, Q2B, Q1C, and Q2C by referring to test case information corresponding to the identification information IDT[5] stored in the test case storage 331 upon notification of test period start notification information of a test period of a positive polarity or a test period of a negative polarity from the current acquisition unit 3302 (step S346). The command unit 301 outputs a closing command signal to the relays ReA, ReB, and ReC. The command unit 301 maintains the relay ReD in a closed state and maintains the switching elements Q1D and Q2D in an ON state. Then, the current acquisition unit 3302 acquires current values measured by the ammeters 312A, 312B, and 312C during the test period of the positive polarity or the test period of the negative polarity and notifies the determination unit 3304 of current value information indicative of the acquired current value (step S347). Next, the command unit 301 outputs an ON command signal to the switching elements Q1A, Q2A, Q1B, Q2B, Q1C, and Q2C upon notification of test period end notification information from the current acquisition unit 3302 (step S348). Subsequently, as illustrated in FIG. 25, the determination unit 3304 determines whether or not there is a phase for which an absolute value |dI| of the current value indicated by the current value information received from the current acquisition unit 3302 is smaller than the current threshold value |dIth| (step S349). Assume that the determination unit 3304 determines that there is a phase for which the absolute value |dI| of the current value is smaller than the current threshold value |dIth| (step S349: Yes). In this case, the determination unit 3304 determines that the relay ReA (ReB, ReC) of the bidirectional switch 1A (1B, 1C) corresponding to the phase for which the absolute value |dI| of the current value is smaller than the current threshold value |dIth| has an open fault (step S350), and the fault determining processing is finished.

On the other hand, assume that the determination unit 3304 determines that the absolute value |dI| of the current value is equal to or larger than the current threshold value |dIth| for all phases (step S349: No). In this case, the command unit 301 outputs an opening command signal to the relays ReA and ReD and outputs an OFF command signal to the switching elements Q1A and Q2A by referring to test case information corresponding to the identification information IDT[6] stored in the test case storage 331 upon notification of test period start notification information of a test period of a positive polarity from the current acquisition unit 3302 (step S351). The command unit 301 outputs an ON command signal to the switching elements Q1D and Q2D. The command unit 301 maintains the relays ReB and ReC in a closed state and maintains the switching elements Q1B, Q2B, Q1C, and Q2C in an ON state. Then, the current acquisition unit 3302 acquires a current value measured by the ammeter 312B during the test period of the negative polarity and notifies the determination unit 3304 of current value information indicative of the acquired current value (step S352). Next, the command unit 301 outputs a closing command signal to the relays ReA and ReD and outputs an ON command signal to the switching elements Q1A and Q2A upon notification of test period end notification information from the current acquisition unit 3302 (step S353). Subsequently, the determination unit 3304 determines whether or not an absolute value |dI| of the current value indicated by the current value information received from the current acquisition unit 3302 is smaller than the current threshold value |dIth| (step S354). In a case where the determination unit 3304 determines that the absolute value |dI| of the current value is smaller than the current threshold value |dIth| (step S354: Yes), the determination unit 3304 determines that the switching element Q2D has an open fault (step S355), and the fault determining processing is finished.

On the other hand, assume that the determination unit 3304 determines that the absolute value |dI| of the current value is equal to or larger than the current threshold value |dIth| (step S354: No). In this case, the command unit 301 outputs an opening command signal to the relays ReA and ReD and outputs an OFF command signal to the switching elements Q1A and Q2A again upon notification of test period start notification information of a test period of a negative polarity from the current acquisition unit 3302 (step S356). The command unit 301 outputs an ON command signal to the switching elements Q1D and Q2D. The command unit 301 maintains the relays ReB and ReC in a closed state and maintains the switching elements Q1B, Q2B, Q1C, and Q2C in an ON state. Then, the current acquisition unit 3302 acquires a current value measured by the ammeter 312B during the test period of the negative polarity and notifies the determination unit 3304 of current value information indicative of the acquired current value (step S357). Next, the command unit 301 outputs a closing command signal to the relays ReA and ReD and outputs an ON command signal to the switching elements Q1A and Q2A upon notification of test period end notification information from the current acquisition unit 3302 (step S358). Subsequently, the determination unit 3304 determines whether or not an absolute value |dI| of the current value indicated by the current value information received from the current acquisition unit 3302 is smaller than the current threshold value |dIth| (step S359). In a case where the determination unit 3304 determines that the absolute value |dI| of the current value is smaller than the current threshold value |dIth| (step S359: Yes), the determination unit 3304 determines that the switching element Q1D has an open fault (step S355), and the fault determining processing is finished.

On the other hand, assume that the determination unit 3304 determines that the absolute value |dI| of the current value is equal to or larger than the current threshold value |dIth| (step S359: No). In this case, the command unit 301 outputs an opening command signal to the relay ReA and outputs an OFF command signal to the switching elements Q1A, Q2A, Q1D, and Q2D by referring to test case information corresponding to the identification information IDT[7] stored in the test case storage 331 upon notification of test period start notification information of a test period of a positive polarity or a test period of a negative polarity from the current acquisition unit 3302 (step S360). The command unit 301 outputs a closing command signal to the relay ReD. The command unit 301 maintains the relays ReB and ReC in a closed state and maintains the switching elements Q1B, Q2B, Q1C, and Q2C in an ON state. Then, the current acquisition unit 3302 acquires a current value measured by the ammeter 312B during the test period of the positive polarity or the test period of the negative polarity and notifies the determination unit 3304 of current value information indicative of the acquired current value (step S361). Next, the command unit 301 outputs a closing command signal to the relay ReA and outputs an ON command signal to the switching elements Q1A, Q2A, Q1D, and Q2D upon notification of test period end notification information from the current acquisition unit 3302 (step S362). Subsequently, the determination unit 3304 determines whether or not an absolute value |dI| of the current value indicated by the current value information received from the current acquisition unit 3302 is smaller than the current threshold value |dIth| (step S363). In a case where the determination unit 3304 determines that the absolute value |dI| of the current value is smaller than the current threshold value |dIth| (step S363: Yes), the determination unit 3304 determines that the relay ReD has an open fault (step S364), and the fault determining processing is finished. On the other hand, in a case where the determination unit 3304 determines that the absolute value |dI| of the current value is equal to or larger than the current threshold value |dIth| (step S363: No), the determination unit 3304 determines that all of the bidirectional switches 1A, 1B, 1C, and 1D have no fault and are normal (step S365), and the fault determining processing is finished.

As described above, according to the switching module 3501 according to the present preferred embodiment, the command unit 301 outputs an opening command signal to the relays ReA and ReD and outputs a closing command signal to the relays ReB and ReC. The determination unit 3304 determines that at least one of the relays ReA and ReD has a short-circuit fault in a case where an absolute value of a current value of a current measured by the ammeter 312B is equal to or smaller than a current threshold value. Therefore, even in a case where impedances of the power conversion circuits 201, 202, 203, and 204 connected to the output terminals te3A and te3B are equal, it is possible to determine whether or not the relay ReD has a fault, and it is therefore possible to detect the presence or absence of a fault for all of the relays ReA, ReB, and ReD included in the switching module 2501.

Although the preferred embodiments of the present invention have been described above, the present invention is not limited to the configurations of the preferred embodiments. For example, in Preferred Embodiments 1 and 2, the determination unit 304 or 2304 may determine whether or not the relays ReA, ReB, ReC, and ReD or the switching elements Q1A, Q2A, Q1B, Q2B, Q1C, Q2C, Q1D, and Q2D have a short-circuit fault or an open fault not on the basis of an absolute value of a difference voltage, but on the basis of whether or not a difference voltage itself, which can take both positive and negative values, is within a preset voltage range. Specifically, a lower limit of the voltage range may be set to about “−14 V”, and an upper limit of the voltage range may be set to about “15 V”, for example. That is, the voltage range may be set so that an absolute value of the lower limit of the voltage range and an absolute value of the upper limit of the voltage range are different from each other. Also in Preferred Embodiment 3, the determination unit 3304 may determine whether or not the relays ReA, ReB, ReC, and ReD or the switching elements Q1A, Q2A, Q1B, Q2B, Q1C, Q2C, Q1D, and Q2D have a short-circuit fault or an open fault not on the basis of an absolute value of a current value, but on the basis of whether or not a current value itself, which can take both positive and negative values, is within a preset current range. That is, the current range may be set so that an absolute value of a lower limit of the current range and an absolute value of an upper limit of the current range are different from each other.

In Preferred Embodiment 1, the voltage acquisition unit 302 may acquire a voltage value measured by the voltmeter 12C and a voltage value measured by the voltmeter 13C in a state where the command unit 301 outputs an opening command signal to the relays ReA and ReD and outputs an OFF command signal to the switching elements Q1A, Q2A, Q1D, and Q2D. Then, the determination unit 304 may determine whether or not the bidirectional switch 1D has a short-circuit fault on the basis of an absolute value of a difference voltage between these voltage values. Alternatively, the voltage acquisition unit 302 may acquire a voltage value measured by the voltmeter 12A (12C) and a voltage value measured by the voltmeter 13A (13C) in a state where the command unit 301 outputs an opening command signal to the relays ReB and ReD and outputs an OFF command signal to the switching elements Q1B, Q2B, Q1D, and Q2D. Then, the determination unit 304 may determine whether or not the bidirectional switch 1D has a short-circuit fault on the basis of an absolute value of a difference voltage between these voltage values.

In each preferred embodiment, the controller 300 may be included in the switching module. The switching module may include only a part (for example, the command unit 301) of the controller 300. Alternatively, the switching module may include a set of a single module body and a single controller.

Various preferred embodiments and modifications are encompassed within the present invention without departing from broad spirit and scope of the present invention. The above preferred embodiments are given for the purpose of illustrating the present invention and do not limit the scope of the present invention. That is, the scope of the present invention is indicated not by the preferred embodiments but by the claims. Various modifications made within the range of the claims and within the range equivalence to the claims are regarded as being encompassed within the scope of the present invention.

Preferred embodiments of the present invention are suitable as power source systems for servers.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A switching module connected to an alternating-current power source including a plurality of polar terminals to output alternating-current voltages including different phases and a neutral terminal, the switching module comprising:
a plurality of first input terminals each of which is connected to a corresponding one of the plurality of polar terminals;
a plurality of first switches each of which is connected in series with a corresponding one of the plurality of first input terminals;
a second input terminal connected to the neutral terminal of the alternating-current power source;
a second switch connected in series with the second input terminal;
a plurality of first output terminals each of which is electrically connected to a corresponding one of the plurality of first input terminals with a corresponding one of the first switches interposed therebetween;
a second output terminal electrically connected to the second input terminal with the second switch interposed therebetween;
a controller configured or programmed to control each of the plurality of first switches and the second switch;
first voltmeters to measure a first voltage between a corresponding one of the plurality of first input terminals and the second input terminal; and
second voltmeters to measure a second voltage between a corresponding one of the plurality of first output terminals and the second output terminal; wherein
the controller is configured or programmed to perform a first determination, in which the controller controls any one of the plurality of first switches to an opened state, controls all others of the first switches to a closed state, and controls the second switch to an opened state, and determines that at least one of the first switch controlled to the closed state and the second switch have a short-circuit fault in a case where a difference voltage between a first voltage measured by the first voltmeter connected to the first switch controlled to the opened state and the second voltage is within a preset voltage range.

2. The switching module according to claim 1, wherein in addition to the first determination, the controller is configured or programmed to perform a second determination, in which the controller controls the any one of the plurality of first switches to the opened state and controls the plurality of first switches excluding the first switch controlled to the opened state and the second switch to the closed state, and determines that the first switch controlled to the opened state has a short-circuit fault in a case where the difference voltage between a first voltage of the first voltmeter connected to the first switch controlled to the opened state and the second voltage is within the voltage range and determines that the second switch has a short-circuit fault in a case where the difference voltage is outside the voltage range.

3. The switching module according to claim 1, further comprising:
a plurality of first switching elements each of which is connected in parallel with a corresponding one of the plurality of first switches; and
a second switching element connected in parallel with the second switch; wherein
the controller is configured or programmed to control the plurality of first switching elements and the second switching element to an ON state while the plurality of first switches are in an opened state, and in a case where there is a phase for which the difference voltage is outside the voltage range, the controller is configured or programmed to determine that one of the first switching elements corresponding to the phase for which the difference voltage is outside the voltage range has an open fault.

4. The switching module according to claim 3, wherein the controller is configured or programmed to control the plurality of first switches to a closed state while the plurality of first switching elements are in an OFF state, and in a case where there is a phase for which the difference voltage between the first voltage and the second voltage is outside the preset voltage range, the controller is configured or programmed to determine that a first switch corresponding to the phase for which the difference voltage is outside the voltage range has an open fault.

5. The switching module according to claim 3, wherein the controller is configured or programmed to control the second switching element to an ON state while any one of the plurality of first switches and a first switching element connected in parallel with the any one of the plurality of first switches are in an opened state and the second switch is in an opened state, and in a case where a difference voltage between the second voltage measured by the second voltmeter connected to the second switching element and a first voltage of the first voltmeter connected to the first switch controlled to the opened state is outside the voltage range, the controller is configured or programmed to determine that the second switching element has an open fault.

6. The switching module according to claim 3, wherein the controller is configured or programmed to control the second switch to a closed state while the plurality of first switches are in a closed state and the second switching element is in an OFF state, and in a case where the difference voltage corresponding to the second switch is outside the voltage range, the controller is configured or programmed to determine that the second switch has an open fault.

7. The switching module according to claim 1, wherein the alternating-current power source is a three-phase four-wire system.

8. The switching module according to claim 1, wherein
a number of the plurality of first input terminals is three;
a number of the plurality of first output terminals is three; and
a number of the plurality of first switches is three.

9. The switching module according to claim 1, further comprising two module bodies controlled by the controller.

10. A power source system comprising:
the switching module according to claim 1; wherein
the power source system is an uninterruptible power source system to supply power to a data center.

11. A switching module connected to an alternating-current power source including a plurality of polar terminals to output alternating-current voltages including different phases and a neutral terminal, the switching module comprising:
a plurality of first input terminals each of which is connected to a corresponding one of the plurality of polar terminals;
a plurality of first switches each of which is connected in series with a corresponding one of the plurality of first input terminals;
a second input terminal connected to the neutral terminal of the alternating-current power source;
a second switch connected in series with the second input terminal;
first output terminals each of which is electrically connected to a corresponding one of the plurality of first input terminals with a corresponding one of the first switches interposed therebetween;
a second output terminal electrically connected to the second input terminal with the second switch interposed therebetween;
a controller configured or programmed to control each of the plurality of first switches and the second switch;
first ammeters to measure a first current flowing through a corresponding one of the plurality of first switches; and
second ammeter to measure a second current flowing through the second switch; wherein
the controller is configured or programmed to perform a first determination, in which the controller controls any one of the plurality of first switches to an opened state and controls the plurality of first switches excluding the first switch controlled to the opened state and the second switch to a closed state, and determines that the first switch controlled to the opened state has a short-circuit fault in a case where a current value of the first current is outside a preset current range.

12. The switching module according to claim 11, wherein in addition to the first determination, the controller is configured or programmed to perform a second determination, in which the controller controls the any one of the plurality of first switches and the second switch to an opened state and the plurality of first switches excluding the first switch controlled to the opened state to a closed state, and determines that the second switch has a short-circuit fault in a case where a current value of the second current is outside the current range.

13. The switching module according to claim 11, further comprising:
a plurality of first switching elements each of which is connected in parallel with a corresponding one of the plurality of first switches; and
a second switching element connected in parallel with the second switch between the second input terminal and the second output terminal; wherein
the controller is configured or programmed to control the plurality of first switching elements to an ON state while the plurality of first switches are in an opened state and the second switching element is in an ON state, and in a case where there is a first switching element for which the current value of the first current is within the current range, the controller, the controller is configured or programmed to determine that the first switching element for which the current value of the first current is within the current range has an open fault.

14. The switching module according to claim 13, wherein the controller is configured or programmed to control the plurality of first switches to a closed state and control at least one of the second switching element and the second switch to a closed state while the plurality of first switching elements are in an ON state, and in a case where there is a phase for which the current value of the first current is within the current range, the controller is configured or programmed to determine that a first switch corresponding to the phase for which the current value of the first current is within the current range has an open fault.

15. The switching module according to claim 13, wherein the controller is configured or programmed to control the second switching element to an ON state while any one of the plurality of first switches and the second switch are in an opened state, others of the first switches are in a closed state, and first switching elements connected in parallel with the first switches that are in the closed state are in an OFF state, and in a case where the current value of the second current is within the current range, the controller is configured or programmed to determine that the second switching element has an open fault.

16. The switching module according to claim 13, wherein the controller is configured or programmed to control the second switch to a closed state while the plurality of first switches are in a closed state and the second switching element is in an OFF state, and in a case where the current value of the second current is within the current range, the controller is configured or programmed to determine that the second switch has an open fault.

17. The switching module according to claim 11, wherein the alternating-current power source is a three-phase four-wire system.

18. The switching module according to claim 11, wherein
a number of the plurality of first input terminals is three;
a number of the plurality of first output terminals is three; and
a number of the plurality of first switches is three.

19. The switching module according to claim 11, further comprising two module bodies controlled by the controller.

20. A power source system comprising:
the switching module according to claim 11; wherein
the power source system is an uninterruptible power source system to supply power to a data center.
